(19) United States
(12) Patent Application Publication
(10) Pub. No.: US 2002/0020917 A1
(43) Pub. Date: Feb. 21, 2002

(54) Semiconductor device and manufacturing process

(76) Inventors: Toshiyuki Hirota, Tokyo (JP); Mitsunari Sukekawa, Tokyo (JP)

Correspondence Address: Darryl G. Walker, WALKER & SAKO, LLP, Suite 235, 300 South First Street, San Jose, CA, 95113, US

(21) Appl. No.: 09/917,319

(22) Filed: Jul. 27, 2001

(30) Foreign Application Priority Data
Jul. 31, 2000 (JP) 2000-231068

(51) Int. Cl. H01L 23/48; H01L 23/52; H01L 29/40

(52) U.S. Cl. 257/758

(57) ABSTRACT

A semiconductor device invention provides a semiconductor device which may minimize increase of cross-talk or interconnection delay, provide stable signal properties and operate with a higher speed, and a manufacturing process whereby such a semiconductor device may be readily manufactured is provided. The semiconductor device can include a conductor (2a) electrically connected to a reference potential, a conductor (4a) acting as a signal interconnection and separated from the conductor (2a) by a dielectric layer (3a). The semiconductor device can also include an adjacent conductor acting as an adjacent signal interconnection and separated from conductor (4a) by an insulation layer. The capacitance from conductor (4a) to conductor (2a) is greater than the capacitance from the adjacent conductor to conductor (4a).

### TECHNICAL FIELD

The present invention relates generally to a semiconductor device and a manufacturing process and more particularly an interconnection structure in an integrated circuit and a process for forming the interconnection structure.

### BACKGROUND OF THE INVENTION

In semiconductor devices, improved processing techniques have led to finer device and wiring/interconnect geometries. Additionally devices can include more layers. Distances between adjacent interconnections have become smaller. These distances include vertical separations and horizontal separations with respect to the substrate plane. The decrease in adjacent interconnect separation has increased capacitance between adjacent interconnections which consequently increases “cross-talk”. Also, this can increase an interconnection delay by increasing the RC time constant, where R is the resistance of the interconnect and C is the capacitance of the interconnect.

In order to achieve high-speed operation, signals may be transmitted at a high frequency. In the area outside of a semiconductor device, a transmission line can be used so that even a high-frequency single can be stably transmitted. However, signals internally transmitted on the semiconductor device can be problematic.

In order to reduce high frequency transmission problems, a conventional approach to reducing capacitance between interconnections is to use a low dielectric constant material for an insulating film formed between the interconnections.

An example of this approach is set forth in Japanese Patent Application Laid-Open 10-189716. In this case, first and second interconnection layers are formed. The first interconnection layer has a shorter distance between adjacent interconnections then the second interconnection layer. A first insulating film is selectively formed in a region with a shorter distance between adjacent interconnections. A second interlayer insulating film is formed in a region with the longer distance between adjacent interconnections. The first insulating film has a lower dielectric constant than the second insulating film. A damascene process is used to from the interconnections. A trench is formed in the insulating film. A metal layer is formed filling the trench. A chemical mechanical polish (CMP) is then performed to remove excess metal.

Also, a variety of shield structures have been proposed for reducing cross-talk between adjacent interconnections.

One such shield structure on a semiconductor device is illustrated in Japanese Patent Application Laid Open 1-94639 (JP-A 1-94639). In such a case, a shield interconnection having a predetermined fixed potential, such as ground, is formed over a region along the longitudinal direction of a signal interconnection. An embodiment of the semiconductor device illustrated in JP-A 1-94639 will be described with reference to FIG. 29.

Referring now to FIG. 29, a cross-section of a semiconductor device is set forth. The semiconductor device of FIG. 29 includes a silicon substrate 101, an insulating film 102, an interlayer insulating film 103, a small signal interconnection 104, a signal interconnection 105, a low resistance interconnection 106, a field oxide film 107, and a dopant diffusion layer 108. The low resistance interconnection 106 acts as a shield interconnection to shield small signal interconnection 104.

In Japanese Patent Application Laid Open 4-239751 (JP-A 4-239751), a process for forming a multi-layer interconnection structure in one main surface of a semiconductor substrate is disclosed. The process includes forming interconnections, depositing an insulating film over the whole surface with a thickness of one-half or less of the minimum distance between the interconnections, depositing a conductive material over the whole surface, etching back the material by anisotropy etching and leaving a side-wall layer made of the conductive material on the side of and separated from the interconnection by the insulating film. The side-wall layer forms the shield layer. An embodiment of the semiconductor device illustrated in JP-A 4-239751 will be described with reference to FIG. 30.

Referring now to FIG. 30, a cross-section of a semiconductor device is set forth. The semiconductor device of FIG. 30 includes a semiconductor substrate 201, a first insulating film 202, a lower interconnection 203, a second insulating film 204, a shield layer 205, an interlayer insulating film 206, an opening 207, and an upper interconnection 208. The shield layer 205 acts to shield the lower interconnection 203.

In Japanese Patent Application Laid Open 4-343433 (JP-A 4-343433), a semiconductor device having a shielded signal interconnection is disclosed. A semiconductor substrate may have an insulating film on which a first conductor layer is formed. The first conductor layer is connected to a ground potential. A first interlayer insulating film is formed on a surface including the first conductor layer. A signal interconnection is formed on the first interlayer insulating film. A second interlayer insulating film is formed on a surface including the signal interconnection. A second conductor layer is formed on the second interlayer insulating film. The second conductor layer is connected to the ground potential. The first and second conducting layers form a shield. An embodiment of the semiconductor device illustrated in JP-A 4-343433 will be described with reference to FIG. 31.

Referring now to FIG. 31, a cross-section of a semiconductor device is set forth. The semiconductor device of FIG. 31 includes a semiconductor substrate 301, an insulating film 302, metal layers (303 and 307), interlayer insulating films (304 and 306), and a signal interconnection 305. Metal layers (303 and 307) act to shield the signal interconnection 305.

In Japanese Patent Application Laid Open 8-274167 (JP-A 2-274167), a semiconductor device having a clock signal shielded on four sides is disclosed. The semiconductor device has first interconnections disposed on both sides of, and separated from a clock interconnection by insulating layers with a predetermined width. Second interconnections are formed above and below the clock interconnection and separated from the clock interconnection by insulating films having a predetermined thickness. The first and second interconnections are connected to at least one reference potential. The first and second interconnections form a shield for the clock interconnection. An embodiment of the semiconductor device illustrated in JP-A 2-274167 will be described with reference to FIG. 32(a) and (b).

Referring now to FIG. 32(a) and (b), cross-sections of an interconnection and shield structure on semiconductor devices are set forth. The interconnection and shield structure of FIG. 32(a) and (b) includes a clock interconnection 401, interconnections (402 and 403), through hole 404, ground (GND) interconnections (405 and 406), and a source interconnection 407.

In Japanese Patent Application Laid Open 61-51847 (JP-A 61-51847), a semiconductor device having a multi-layered interconnection structure is disclosed. The semiconductor device has a multi-layered interconnection structure where interconnection layers are composed of at least three conductor films. Insulating films for the interconnection layers are alternately laminated on a semiconductor substrate. Among the multi-layered interconnections, the interconnection of the second layer (intermediate layer) is laterally and vertically sandwiched by the interconnections of the first layer (lower layer) and the third layer (upper layer) to form a shield structure. An embodiment of the semiconductor device illustrated in JP-A 61-51847 will be described with reference to FIG. 33.

Referring now to FIG. 33, a cross-section of a semiconductor device is set forth. The cross-section of FIG. 33 includes a p⁻-type silicon substrate 501, an epitaxial n⁻-type layer 502, a first layer interconnection 505, a second layer interconnection 506, a third layer interconnection 507, and a first interlayer insulating film 508, a second interlayer insulating film 509, and a protective insulating film 510.

In Japanese Patent Application Laid Open 7-307567 (JP-A 7-307567), a semiconductor device having a film multilayered interconnection substrate is disclosed. A signal layer is sandwiched by a ground layer and a source layer formed continuously, or as a mesh over a large area. A film capacitor is formed as a bypass capacitor by disposing a ground layer and a source layer between the signal layer and the substrate. It is described that such a structure allows a signal to be properly processed by preventing exogenous noise from entering the signal layer. An embodiment of the semiconductor device illustrated in JP-A 7-307567 will be described with reference to FIG. 34(a) and (b).

Referring now to FIG. 34(a) and (b), cross-sections of a semiconductor device is set forth. The cross-section of FIG. 34(a) includes a substrate 601, source layers (611 and 605), a capacitance insulating film 612, a ground layer 602, a film capacitor 613, a first signal layer 603b, a second signal layer 604b, a pad layer 606, interlayer insulating films (608-a to 608-d), via holes (609-a and 609-b), and a thermal via hole 610. The cross-section of FIG. 34(b) includes ground layers (606a and 641), a source layer 622, a capacitance insulating film 644. Capacitance insulating film 644 consists of a Ta₂O₅ film 642 and a polyimide film 643.

In Japanese Patent Application Laid Open 60-134440 (JP-A 60-134440), a semiconductor device having a conventional-type transmission line is disclosed. The semiconductor device has a relatively large size with a pair of signal interconnections having an interconnection length on the order of a centimeter (cm). The signal interconnections connect difference circuits and complementary signals may be transmitted to these signal interconnections for generating electromagnetic coupling to minimize cross-talk between adjacent interconnections. An embodiment of the semiconductor device illustrated in JP-A 60-134440 will be described with reference to FIG. 35(a) while FIG. 35(b) illustrates a conventional example.

Referring now to FIG. 35(a) and (b), cross-sections of a semiconductor device is set forth. The cross-sections of FIG. 35(a) and 35(b) include signal interconnections (707, 708, 711, and 712) in which complementary signals are transmitted to paired interconnections and ground source layers (709, 710, and 713) for preventing interference with upper and lower interconnections (not shown) in a multi-layered interconnection structure. Interlayer insulating films (not shown) are formed between interconnections and between a signal interconnection and a ground/source layer. It is described that the structure of FIG. 35(a) allows a large parallel surface area between interconnections, resulting in a large magnetic coupling between interconnections and thus, reduced cross-talk between adjacent interconnections.

However, as devices become finer and operate at higher speeds, problems associated with cross-talk and interconnection delays due to the increased capacitance between interconnections have become increasingly significant.

Furthermore, when transmitting a signal at a operation frequency of more than a G (giga) Hz in a conventional structure, the inductance of an interconnection itself, such as a source line or ground line, can no longer be ignored even in a fine region within a semiconductor device. Thus, the inductance of the interconnection itself can become critical factor in the acceleration of signal transmissions.

Also, a manufacturing process that reduces production costs for a device is needed.

In view of the above discussion, it would be desirable to provide a semiconductor device, which can minimize cross-talk. It would also be desirable to provide a semiconductor device with stable signal properties. It would be desirable to provide a semiconductor device that can transmit signals having higher speeds or frequencies. It would be desirable to provide a semiconductor device having a manufacturing process for achieving the above.

### SUMMARY OF THE INVENTION

According to the present embodiments, a semiconductor device invention provides a semiconductor device which may minimize increase of cross-talk or interconnection delay, provide stable signal properties and operate with a higher speed, and a manufacturing process whereby such a semiconductor device may be readily manufactured is provided. The semiconductor device can include a first conductor electrically connected to a reference potential, a second conductor acting as a signal interconnection and separated from the first conductor by a dielectric layer. The semiconductor device can also include an adjacent conductor acting as an adjacent signal interconnection and separated from the second conductor by an insulation layer. The capacitance from the first conductor to the second conductor is greater than the capacitance from the adjacent conductor to second conductor.

According to one aspect of the embodiments, a semiconductor device may include a first conductor electrically connected to a reference potential. A second conductor may act as a first signal interconnection and may be separated from the first conductor by a first dielectric layer. A third conductor may act as a second signal interconnection and may be adjacent to the second conductor. A first insulating film may be between the second and third conductors. A first capacitance between the second conductor and the first conductor may be larger than the capacitance between the second conductor and the third conductor.

According to another aspect of the embodiments, the first dielectric layer may have a thickness that is smaller than the distance between the second and third conductors.

According to another aspect of the embodiments, the first insulating film may have a dielectric constant smaller than the first dielectric layer.

According to another aspect of the embodiments, a fourth conductor may be electrically connected to the reference potential. A second dielectric layer may be disposed between the second and fourth conductors.

According to another aspect of the embodiments, the first and second dielectric layers may each have a thickness smaller than a distance between the second and third conductors.

According to another aspect of the embodiments, the first insulating film may have a dielectric constant smaller than the dielectric constants of the first and second dielectric layers.

According to another aspect of the embodiments, the first and second conductors may be disposed in parallel and may be separated by the first dielectric layer. The second and fourth conductors may be disposed in parallel and may be separated by the second dielectric layer.

According to another aspect of the embodiments, the first and second conductors may be disposed in parallel and are separated by the first dielectric layer.

According to another aspect of the embodiments, the first and third conductors may be disposed in parallel and may be separated by the first dielectric layer.

According to another aspect of the embodiments, the second conductor may be formed in a first trench having a predetermined pattern. The third conductor may be formed in a second trench having a predetermined pattern.

According to another aspect of the embodiments, the first conductor, first dielectric layer and second conductor may be formed in a trench having a predetermined pattern.

According to another aspect of the embodiments, the first conductor is separated from a bottom surface and at least a portion of a side surface of the second conductor by the first dielectric layer.

According to another aspect of the embodiments, the first conductor layer and the second conductor layer may form a transmission line.

According to another aspect of the embodiments, a semiconductor device may include a first conductor layer on a first interlayer insulating. The first conductor layer may be electrically connected to a reference potential. A first dielectric layer may be formed on the first conductor layer. A signal interconnection may be formed on the first dielectric layer. A second conductor layer may be separated from the signal interconnection by a second dielectric layer and may cover an upper surface and at least a portion of a side surface of the signal interconnection. The second conductor layer may be electrically connected to the reference potential.

According to another aspect of the embodiments, the whole top surface and side surface of the signal interconnection may be covered by the second conductor layer.

According to another aspect of the embodiments, the first conductor layer may have a planar surface. A plurality of signal interconnections may face and may be separated from the planar surface by the first dielectric layer.

According to another aspect of the embodiments, the semiconductor device may include an adjacent signal interconnection on the first dielectric layer. The first and second conductor layers may be electrically connected through a region between the signal interconnection and the adjacent signal interconnection.

According to another aspect of the embodiments, a space between the signal interconnection and an adjacent signal interconnection may be filled by the second conductor.

According to another aspect of the embodiments, the first conductor layer and the signal interconnection may form a transmission line.

According to another aspect of the embodiments, a process for manufacturing a semiconductor device may include the steps of forming a first conductor layer on a first interlayer insulating film, forming a first dielectric layer on the first conductor layer, forming a second interlayer insulating film, forming a trench with a predetermined pattern in the second interlayer insulating film, forming a second conductor layer filling the trench, and polishing the surface to form an interconnection where the second conductor layer may be embedded in the trench.

According to another aspect of the embodiments, the first dielectric layer may act as an etching stopper when forming the trench.

According to another aspect of the embodiments, the process may further include the steps of, forming a second dielectric layer on the surface including the second conductor layer and forming a third conductor layer on the second dielectric layer.

According to another aspect of the embodiments, a process for manufacturing a semiconductor device may include the steps of forming an etching stopper film on a first interlayer insulating film, forming a second interlayer insulating film on the etching stopper film, forming a trench having a predetermined pattern in the second interlayer insulating film, forming a first conductor layer filling the trench, polishing the surface to form a damascene interconnection where the first conductor is embedded in the trench, forming a dielectric layer on the surface including the damascene interconnection, and forming a second conductor layer on the surface including the dielectric layer.

According to another aspect of the embodiments, a process for manufacturing a semiconductor device ma include the steps of forming an etching stopper film on a first interlayer insulating film, forming a second interlayer insulating film on the etching stopper film, forming a trench having a predetermined pattern in the second interlayer insulating film, forming a first conductor layer covering the surface in the trench, forming a dielectric layer covering the surface in the trench, forming a second conductor layer filling the trench, and polishing the surface with a chemical mechanical polish to form a damascene interconnection.

According to another aspect of the embodiments, a process for manufacturing a semiconductor device may include the steps of forming a first conductor layer on a first interlayer insulating film, forming a first dielectric layer on the first conductor layer, forming a second conductor layer on the first dielectric layer, forming a second dielectric layer on the second conductor layer, patterning the first dielectric layer, second conductor layer and the second dielectric layer in a predetermined pattern, forming a side-wall dielectric layer for the first dielectric layer, second conductor layer, and second dielectric layer, and forming a third conductor layer separated by the second conductor layer by the second dielectric layer and the sidewall dielectric layer.

According to another aspect of the embodiments, a semiconductor device may include a plurality of interconnection structures comprising a planar conductor layer electrically connected to a reference potential and a plurality of interconnections facing a surface of the planar conductor layer and separated by a dielectric layer. A first through hole may be formed through the planar conductor layer. A first conductor plug may be formed in the first through hole and may penetrate the planar conductor layer. The first plug may be electrically isolated from the planar conductor.

According to another aspect of the embodiments, the first conductor plug my be electrically connected to a first reference potential. A second through hole may be formed through the planar conductor layer. A second conductive plug may be formed in the second through hole and may be electrically connected to a second reference potential and may penetrate the planar conductor layer. The second plug may be electrically isolated from the planar conductor.

According to another aspect of the embodiments, an insulating film may electrically isolate the first and second plugs from the planar conductor.

According to another aspect of the embodiments, the first through hole and first conductor plug may be formed including the steps of forming the first through hole by penetrating the first conductor layer, forming an insulating film on the inside surface of the first through hole, etching the insulating film to form a side wall insulating film on the side surface of the first through hole, and forming the first conductor plug in the through hole.

According to another aspect of the embodiments, the step of forming the first conductive plug in the through hole ma include filling the through hole with a conductive material and using chemical mechanical polishing to form the first conductive plug.

According to another aspect of the embodiments, the step of forming the first conductive plug in the through hole may include filling the first through hole with a conductive material and an etching step to remove excess conductive material to form the first conductive plug.

According to another aspect of the embodiments, the semiconductor device may include a first conductor electrically connected to a first reference potential. A second conductor may be electrically connected to a second reference potential and may be separated from the first conductor by a dielectric layer and may form a film capacitor. The film capacitor may be formed in a region above a transistor in the semiconductor device. An interconnection structure may include a plurality of third conductors separated from the first conductor by an insulating layer.

According to another aspect of the embodiments, the interconnection structure may include a plurality of fourth conductors separated from the second conductor by a second insulating layer.

### BRIEF DESCRIPTION OF THE DRAWINGS

FIG. 1(a)-(c) are cross-sections of the semiconductor device according to the first embodiment after various processing steps.

FIGS. 2 is a cross-section of the semiconductor device according to the first embodiment after various processing steps.

FIG. 3(a)-(c) are cross-sections of the semiconductor device according to the second embodiment after various processing steps.

FIG. 4(a)-(c) are cross-sections of the semiconductor device according to the third embodiment after various processing steps.

FIG. 5(a)-(c) are cross-sections of the semiconductor device according to the fourth embodiment after various processing steps.

FIG. 6(a)-(c) are cross-sections of the semiconductor device according to the fifth embodiment after various processing steps.

FIG. 7(a)-(d) are cross-sections of the semiconductor device according to the sixth embodiment after various processing steps.

FIG. 8(a)-(d) are cross-sections of the semiconductor device according to the seventh embodiment after various processing steps.

FIG. 9(a)-(d) are cross-sections of the semiconductor device according to the seventh embodiment after various processing steps.

FIG. 10(a)-(d) are cross-sections of the semiconductor device according to the eighth embodiment after various processing steps.

FIG. 11(a)-(d) are cross-sections of the semiconductor device according to the ninth embodiment after various processing steps.

FIG. 12(a)-(d) are cross-sections of the semiconductor device according to the tenth embodiment after various processing steps.

FIG. 13(a)-(e) are cross-sections of the semiconductor device according to the eleventh embodiment after various processing steps.

FIG. 14(a)-(e) are cross-sections of the semiconductor device according to the twelfth embodiment after various processing steps.

FIG. 15(a)-(e) are cross-sections of the semiconductor device according to the thirteenth embodiment after various processing steps.

FIG. 16(a)-(e) are cross-sections of the semiconductor device according to the fourteenth embodiment after various processing steps.

FIG. 17(a)-(e) are cross-sections of the semiconductor device according to the fifteenth embodiment after various processing steps.

FIG. 18(a)-(e) are cross-sections of the semiconductor device according to the sixteenth embodiment after various processing steps.

FIG. 19(a)-(e) are cross-sections of the semiconductor device according to the seventeenth embodiment after various processing steps.

FIG. 20(a)-(e) are cross-sections of the semiconductor device according to the seventeenth embodiment after various processing steps.

FIG. 21(a)-(b) are cross-sections of the semiconductor device according to the seventeenth embodiment after various processing steps.

FIG. 22 is a cross-section of the semiconductor device according to the eighteenth embodiment after various processing steps.

FIG. 23 is a plan view of a conventional semiconductor device.

FIG. 24 is a cross-section of a conventional semiconductor device after various processing steps.

FIG. 25 is a circuit schematic diagram semiconductor device according to the nineteenth embodiment.

FIG. 26 is a plan view of the semiconductor device according to the nineteenth embodiment.

FIG. 27 is a cross-section of the semiconductor device according to the nineteenth embodiment after various processing steps.

FIG. 28 is a cross-section of the semiconductor device according to the twentieth embodiment after various processing steps.

FIG. 29 is a cross-section of a conventional semiconductor device after various processing steps.

FIG. 30 is a cross-section of a conventional semiconductor device after various processing steps.

FIG. 31 is a cross-section of a conventional semiconductor device after various processing steps.

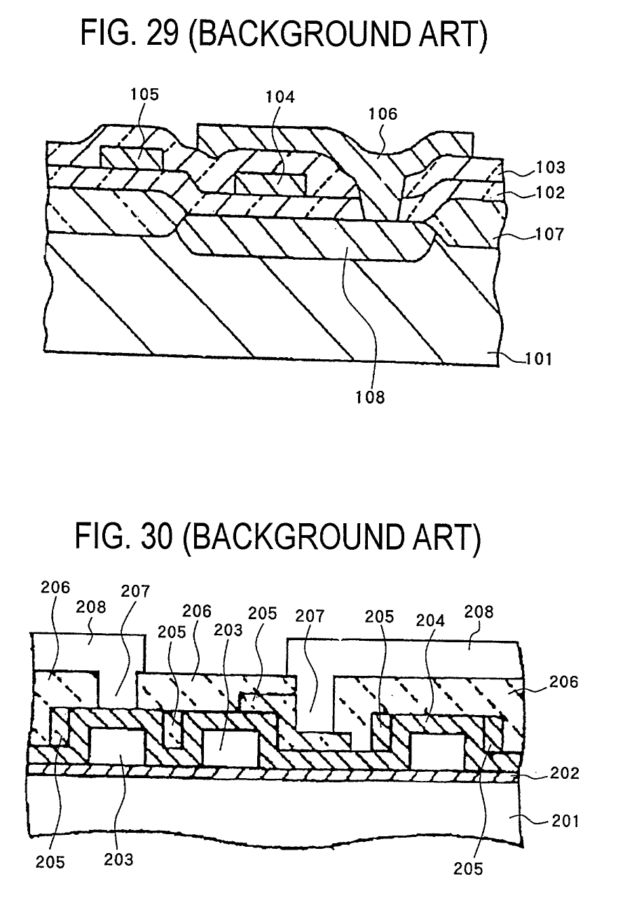

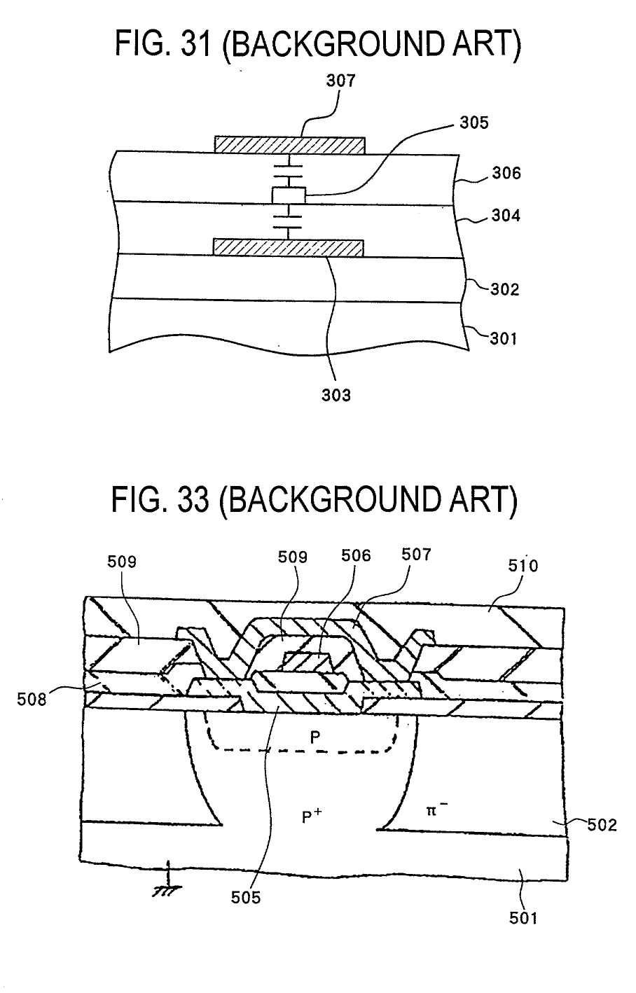

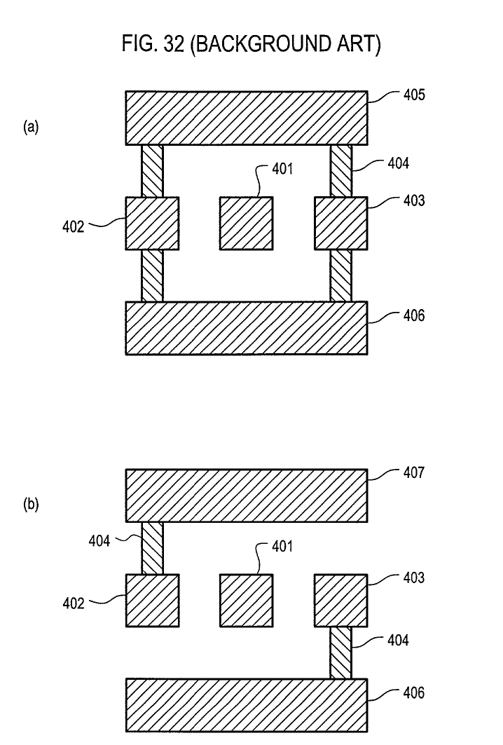

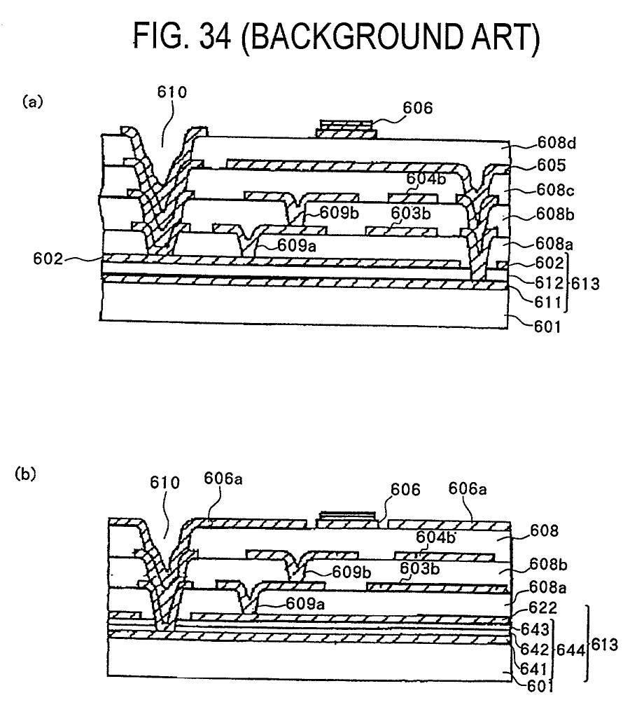

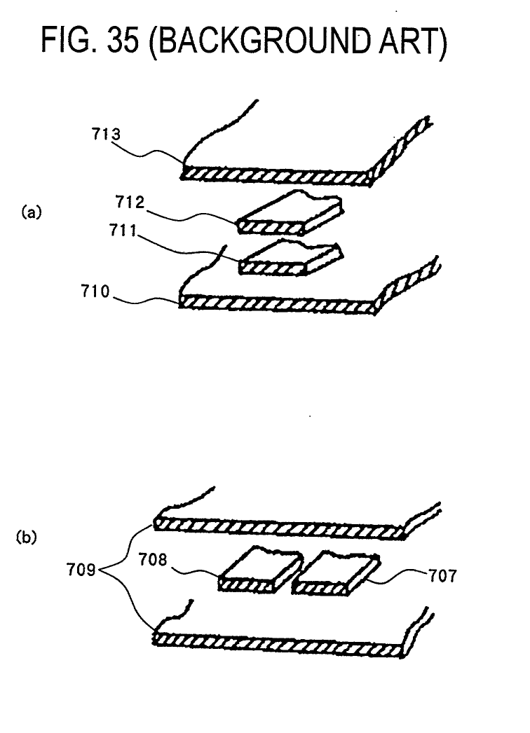

FIG. 29(a)-(b) are cross-sections of a conventional interconnection structure.

FIG. 33 is a cross-section of a conventional semiconductor device after various processing steps.

FIG. 34 is a cross-section of a conventional semiconductor device after various processing steps.

FIG. 35 is a schematic view illustrating a conventional interconnection structure.

### DETAILED DESCRIPTION OF THE EMBODIMENTS

Various embodiments of the present invention will now be described in detail with reference to a number of drawings.

Embodiment 1

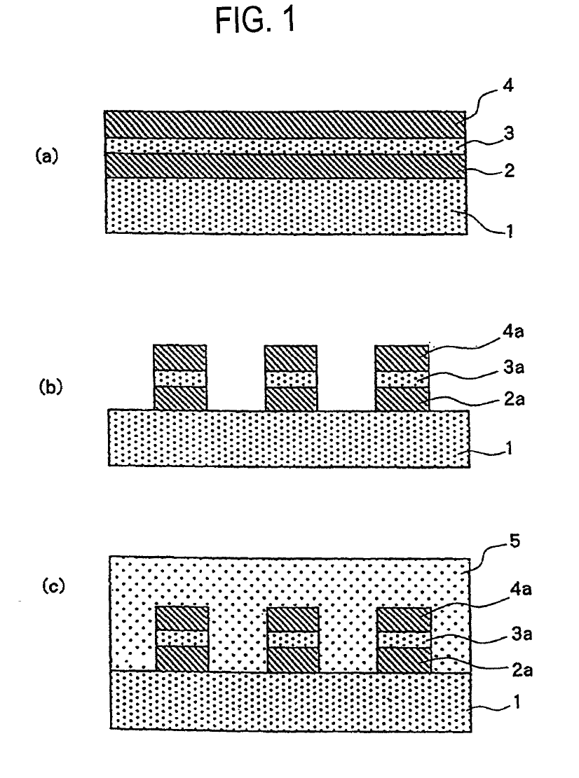

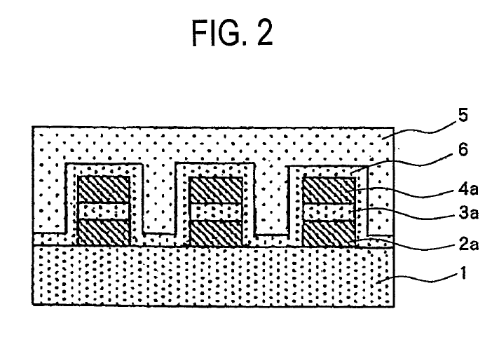

The first embodiment of the present invention is illustrated in FIG. 1(a)-(c) and FIG. 2.

FIG. 1(a)-(c) and FIG. 2 are cross-sections of the semiconductor device according to the first embodiment after various processing steps.

Referring now to FIG. 1(a), a first interlayer insulating film 1, a first conductor layer 2, a dielectric layer 3, and a second conductor layer 4 may be sequentially formed on a main surface of a semiconductor or ceramic substrate (not shown).

First interlayer insulating film 1 may be any known insulating film. In this embodiment, first interlayer insulating film 1 may be a silicon oxide film, which may be formed by plasma-enhanced chemical vapor deposition (PE-CVD). Dielectric layer 3 may be an insulating film with a dielectric constant higher than a second layer insulating film 5 (FIG. 1(c)). In this embodiment, dielectric layer 3 may be a silicon oxide film having a specific dielectric constant of approximately 4.3. Dielectric layer 3 may be formed by PE-CVD. It is preferable that dielectric layer 3 may have a thickness smaller than a distance between adjacent second conductor layers 4a (illustrated in FIG. 1(b)-(c)) that may be formed by a subsequent patterning. First conductor layer 2 and second conductor layer 4 may be formed using a known interconnection material. As one example, a tungsten (W) film may be formed, by sputtering, to a thickness of about 2 nm. In order to improve adhesiveness, a film made of WN or TiN may be formed as a base layer in an interface.

First conductor layer 2, dielectric layer 3, and second conductor layer 4 may be patterned by a known lithography and dry etching technique. The dry etching step is conducted under such conditions that etching may be stopped when first interlayer insulating film 1 is exposed. The resulting conductor layer 2a, dielectric layer 3a, and second conductor layer 4a is illustrated in FIG. 1(b).

A second interlayer insulating film 5 may be formed covering first conductor layer 2a, dielectric layer 3a, and second conductor layer 4a. The resulting interconnection structure is shown in FIG. l(c). Second interlayer insulating film 5 is preferably made of a material having a dielectric constant smaller than that of dielectric layer 3a. In this embodiment, HSQ (hydro-silses-quioxane) may be used as a material for second interlayer insulating film 5. HSQ may have a dielectric constant of about 3.1.

As previously described, it is preferable in this embodiment that dielectric layer 3a has a dielectric constant higher than that of second interlayer insulating film 5. Materials, which may be used for dielectric layers (3 and 3a), include silicon oxide, silicon nitride (SiN), and silicon oxynitride (SiON). Such materials may have a relatively higher dielectric constant. Materials, which may be used for second interlayer insulating film 5, include an organic SOG (spin-on-glass) film, HSQ (hydro-silses-quioxane), polyarylether, fluorinated polyarylether, inorganic polysilazane, organic polysilazane, BCB (benzocyclobutene), MSQ (methyl-silses-quioxane), fluorinated polyimide, plasma CF polymer, plasma CH polymer, Teflon AF®, Parylene N® (polyparaxylylene N), Parylene AF4® (polyparaxylylene F), and polynapthalene N. Also, silicon oxide, silicon nitride (SiN) and silcon oxynitride (SiON) listed as materials with a relatively higher dielectric constant may be used as a low dielectric-constant material in second interlayer insulating film 5 when using a material having a higher dielectric constant than those of these materials in dielectric layers (3 and 3a).

As previously described, dielectric layers (3 and 3a) preferably have a thickness smaller than a distance between adjacent second conductor layers 4a acting as a signal interconnection. In order to ensure insulation, the thickness of dielectric layers (3 and 3a) is preferably greater than or equal to about 20 nm. However, in order to strengthen electrostatic coupling by ensuring a capacitance between pair interconnections and strengthen electromagnetic coupling by inducing in one signal interconnection a current with a phase opposite to that in a current in the other signal interconnection, the thickness of dielectric layers (3 and 3a) is preferably less than or equal to about 300 nm. This may also be conducive in forming a transmission line.

In this embodiment, it is preferable that insulating materials are selected and combined and the thickness of dielectric layers (3 and 3a) are determined depending on an interconnection distance, such that a capacitance (per a unit length) between second conductor layer 4a (signal interconnection) and first conductor layer 2a may be larger than that (per a unit length) between adjacent second conductor layers 4a in the same layer.

In the interconnection structure thus formed, second conductor layer 4a may act as a signal interconnection while first conductor layer 2a is connected to a reference potential, e.g., grounded to act as a ground layer or connected to a source to act as a source layer. On the contrary, first conductor layer 2a may act as a signal interconnection while second conductor layer 4a may act as a ground layer or source layer.

As described above, two conductor layers may be laminated as a pair via an insulating film to form an interconnection (stacked pair line). One conductor layer may be used as a signal interconnection while the other conductor layer is connected to a reference potential so that two conductor layers as a pair may be electrostatically coupled to reduce a crosstalk with an adjacent interconnection.

Two conductor layers may be laminated as a pair via an insulating film to induce in one conductor layer a current with a phase opposite to a current in the other conductor layer (signal interconnection). Thus, forming electromagnetic coupling between these conductor layers whereby a crosstalk with an adjacent interconnection may be reduced.

Furthermore, a configuration where conductor layers are mutually facing via an insulating film to form a transmission line may reduce an effective inductance of the interconnection to permit a signal to be satisfactorily transmitted. Such a transmission line may be formed by making the shapes and the sizes of two conductor layers and the insulating layer between these conductor layers substantially constant in a cross section perpendicular to the longitudinal direction of the interconnection. This may keep an intrinsic impedance constant over the whole area between a signal source and a receiving point and by using the same material for each conductor layer and the insulating layer. In such a transmission line, the facing conductor layers may be disposed at substantially regular intervals over the whole area between the signal source and the receiving point and a width and a thickness of each conductor layer may be substantially constant without a branched structure. A transmission line may be configured to form a return circuit for a signal current. In such a transmission line comprising a pair of the conductor layers, a current that flows in one conductor layer flows in the opposite direction to the direction of a current that flows in the other conductor layer so that a signal may be transmitted.

As described with reference to FIG. 1(b), after patterning three layers, a liner film 6 may be formed for improving moisture resistance and adhesiveness and then second interlayer insulating film 5 may be formed to give a structure illustrated in FIG. 2. Such a liner film may be made of a TEOS oxide film, which can be formed by an appropriate process such as plasma CVD.

Embodiment 2

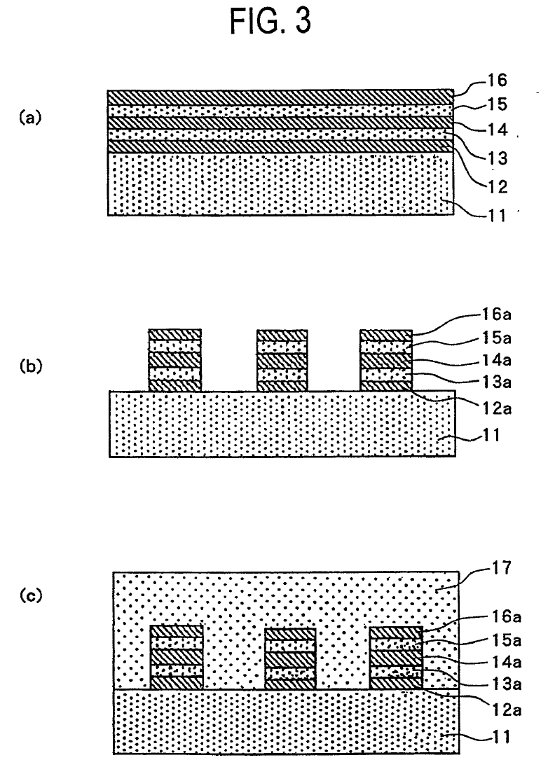

A second embodiment of the present invention is illustrated in FIG. 3(a)-(c).

FIG. 3(a)-(c) are cross-sections of the semiconductor device according to the second embodiment after various processing steps.

Referring now to FIG. 3(a), a first interlayer insulating film 11, a first conductor layer 12, a dielectric layer 13, a second conductor layer 14, second dielectric layer 15, and third conductor layer 16 may be sequentially formed on a main surface of a semiconductor or ceramic substrate (not shown).

First dielectric layer 13 and second dielectric layer 15 are preferably an insulating film with a dielectric constant higher than the second interlayer insulating film 17 formed later. In this embodiment, first and second dielectric layers (13 and 15) are a silicon oxide film (dielectric constant of approximately 4.3) formed by PE-CVD as is first interlayer insulating film 11. In the process, it is preferable that first and second dielectric layers (13 and 15) have a thickness smaller than a distance between adjacent second conductor layers 14a later formed by patterning. First, second and third conductor layers (12, 14, and 16) may be made of a known interconnection material. For example, a tungsten (W) film may be formed to a thickness of about 200 nm using sputtering. In order to improve adhesiveness, a film made of WN or TiN may be formed as a base layer in an interface.

Next, first conductor layer 12, first dielectric layer 13, second conductor layer 14, second dielectric layer 15, and third conductor layer 16 may be patterned by a known lithography and dry etching technique. In the process, the dry etching step may be conducted under such conditions that etching is stopped when the first interlayer insulating film 11 is exposed (FIG. 3(b)).

Next, second interlayer insulating film 17 may be formed covering first conductor layer 12a, first dielectric layer 13a, second conductor layer 14a, second dielectric layer 15a and third conductor layer 16a to provide an interconnection structure shown in FIG. 3(c). Second interlayer insulating film 17 is preferably made of a material having a dielectric constant smaller than that of first and the second dielectric layers (13a and 15a). In this embodiment, HSQ with a dielectric constant of approximately 3.1 may be used as a material for the second interlayer insulating film 17.

As described above, it is preferable that first and second dielectric layers (13a and 15a) have a dielectric constant higher than that of second interlayer insulating film 17, and can be made of any material described for the dielectric layer (3 and 3a) in Embodiment 1. In addition, second interlayer insulating film 17 may be made of any material described for second interlayer insulating film 5 in Embodiment 1. A thickness of the first or second dielectric layer may be determined as described for the dielectric layer in Embodiment 1.

In this embodiment, it is preferable that insulating materials are selected and combined and the thickness of first and second dielectric layers (13a and 15a) are determined depending on an interconnection distance, such that capacitances (per a unit length) between second conductor layer 14a (signal interconnection) and first conductor layer 12a and between second conductor layer 14a and third conductor layer 16a are larger than that (per a unit length) between adjacent second conductor layers 14a in the same layer.

In the interconnection structure thus formed, second conductor layer 14a may act as a signal interconnection while first conductor layer 12a is connected to a reference potential, e.g., grounded to act as a ground layer or connected to a source to act as a source layer. Similarly, third conductor layer 16a may also be connected to a reference potential to act as, for example, a ground or source layer. One of these layers may act as a ground layer while the other as a source layer, or both conductor layers may act as a source or ground layer.

In this embodiment, electrostatic coupling may be formed between the signal interconnection and both conductor layers vertically (i.e., perpendicular to the substrate, plane) sandwiching the signal interconnection so that cross talk can be further reduced.

Two conductor layers may be laminated as a pair, via an insulating film, to induce in one conductor layer a current with a phase opposite to a current in the other conductor layer (signal interconnection). Thus, forming electromagnetic coupling between these conductor layers whereby a crosstalk with an adjacent interconnection may be reduced.

Furthermore, as described in Embodiment 1, a configuration where conductor layers mutually facing via an insulating film to form a transmission line may reduce an effective inductance of the interconnection to permit a signal to be satisfactorily transmitted.

Again in this embodiment, as described in Embodiment 1, after patterning a liner film may be formed for improving moisture resistance and adhesiveness and then second interlayer insulating film 17 may be formed.

Embodiment 3

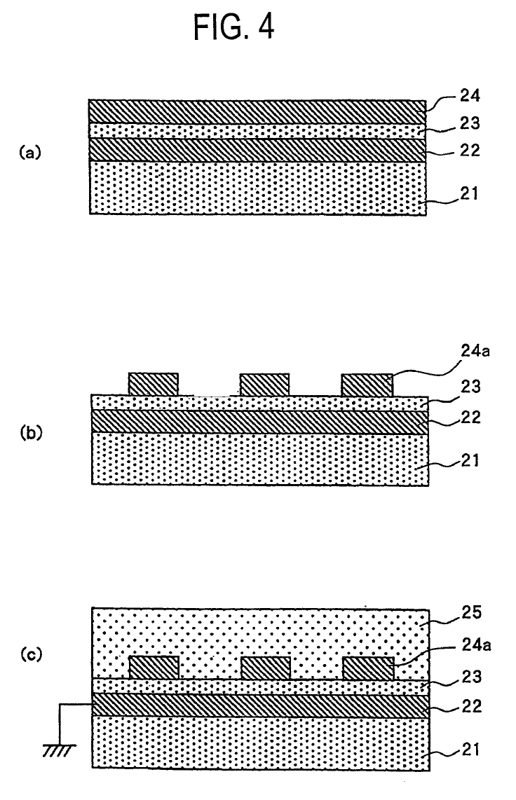

A third embodiment of the present invention is illustrated in FIG. 4(a)-(c).

FIG. 4(a)-(c) are cross-sections of the semiconductor device according to the third embodiment after various processing steps.

Referring now to FIG. 4(a), a first interlayer insulating film 21, a first conductor layer 22, a dielectric layer 23, and a second conductor layer 24 may be sequentially formed on a main surface of a semiconductor or ceramic substrate (not shown).

Dielectric layer 23 is preferably an insulating film with a dielectric constant higher than second interlayer insulating film 25 formed later and may be made of an insulating film as described in Embodiment 1. It is preferable that, as is in Embodiment 1, dielectric layer 23 has a thickness smaller than a distance between adjacent second conductor layers 24a later formed by patterning. First interlayer insulating film 21 and first and second conductor layers (22 and 24) may be formed as usual from a material as described in Embodiment 1.

Next, second conductor layer 24 is patterned by a known lithography and dry etching technique. In the process, the dry etching step may be conducted under such conditions that etching is stopped when the dielectric layer 23 is exposed (FIG. 4(b)).

Next, second interlayer insulating film 25 may be formed covering second conductor layer 24a to provide an interconnection structure shown in FIG. 4(c). Second interlayer insulating film 25 is preferably made of a material having a dielectric constant smaller than that of dielectric layer 23. In this embodiment, as described in Embodiment 1, HSQ with a dielectric constant of approximately 3.1 may be used as a material for the second interlayer insulating film 25 and silicon oxide may be used as a material of the dielectric layer.

In this embodiment, it is preferable that dielectric layer 23 has a dielectric constant higher than that of second interlayer insulating film 25, and may be made of any material described for the dielectric layer in Embodiment 1. In addition, second interlayer insulating film 25 may be made of any material described for the second interlayer insulating film 5 in Embodiment 1. A thickness of dielectric layer 23 may be determined as described for the dielectric layer 3 in Embodiment 1.

In this embodiment, it is preferable that insulating materials are selected and combined and the thickness of dielectric layer 23 is determined depending on an interconnection distance, such that a capacitance (per a unit length) between second conductor layer 24a (signal interconnection) and first conductor layer 22 is larger than that (per a unit length) between adjacent second conductor layers 24a in the same layer.

In the interconnection structure thus formed, second conductor layer 24a may act as a signal interconnection while first conductor layer 22 is connected to a reference potential, e.g., grounded to act as a ground layer or connected to a source to act as a source layer. FIG. 4(c) shows a configuration where the first conductor layer 22 acts as a ground layer.

As described above, an interconnection structure where two conductor films are laminated via an insulating film may be formed and one patterned conductor layer may be used as a signal interconnection while the other planar conductor layer being connected to a reference potential to strengthen mutual electrostatic coupling of the facing conductor layers so that cross talk with an adjacent interconnection may be reduced.

Two conductor layers may be laminated to induce in one planar conductor layer a current with a phase opposite to a current in the other conductor layer (signal interconnection). Thus, forming electromagnetic coupling between these conductor layers whereby a crosstalk with another adjacent interconnection may be reduced.

Furthermore, as described in Embodiment 1, a configuration where conductor layers mutually facing via an insulating film to form a transmission line may reduce an effective inductance of the interconnection to permit a signal to be satisfactorily transmitted. However, in this embodiment, the conductor layer facing the signal interconnection is planar so that a current (a current having a phase opposite to that of a signal current) in the planar conductor layer flows in or near an area facing the signal interconnection. The planar conductor layer facing the signal interconnection may be, therefore, acceptable as long as its shape (e.g., thickness) and composition are substantially even over the whole area between the signal source and the receiving point, at least the area facing the signal interconnection.

Again in this embodiment, as described in Embodiment 1, after patterning second conductor layer 24, a liner film may be formed for improving moisture resistance and adhesiveness and then second interlayer insulating film 25 may be formed.

In this embodiment and Embodiments below, a planar conductor layer may be formed over the whole surface of a substrate, which may eliminate a step of patterning the planar conductor layer.

Embodiment 4

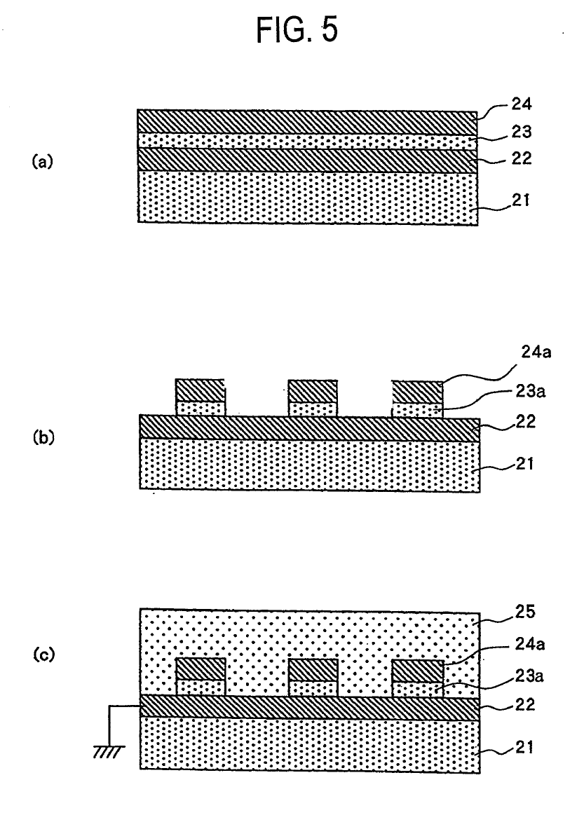

A fourth embodiment of the present invention is illustrated in FIG. 5(a)-(c).

FIG. 5(a)-(c) are cross-sections of the semiconductor device according to the fourth embodiment after various processing steps.

Referring now to FIG. 5(a), a first interlayer insulating film 21, a first conductor layer 22, a dielectric layer 23, and a second conductor layer 24 may be sequentially formed on a main surface of a semiconductor or ceramic substrate (not shown).

Dielectric layer 23 is preferably an insulating film with a dielectric constant higher than second interlayer insulating film 25 formed later and may be made of an insulating film as described in Embodiment 1. It is preferable that, as is in Embodiment 1, dielectric layer 23 has a thickness smaller than a distance between adjacent second conductor layers 24a later formed by patterning. First interlayer insulating film 21 and first and second conductor layers (22 and 24) may be formed as usual from a material as described in Embodiment 1.

Next, second conductor layer 24 and dielectric layer 23 are patterned by a known lithography and dry etching technique. In the process, the dry etching step may be conducted under such conditions that etching is stopped when first dielectric layer 22 is exposed (FIG. 5(b)).

Next, second interlayer insulating film 25 may be formed covering second conductor layer 24a and dielectric layer 23a to provide an interconnection structure shown in FIG. 5(c). Second interlayer insulating film 25 is preferably made of a material having a dielectric constant smaller than that of dielectric layer 23. In this embodiment, as described in Embodiment 1, HSQ with a dielectric constant of approximately 3.1 may be used as a material for the second interlayer insulating film 25 and silicon oxide may be used as a material of the dielectric layer.

In this embodiment, it is preferable that dielectric layer 23 has a dielectric constant higher than that of second interlayer insulating film 25, and may be made of any material described for the dielectric layer in Embodiment 1. In addition, second interlayer insulating film 25 may be made of any material described for the second interlayer insulating film 5 in Embodiment 1. A thickness of dielectric layer 23 may be determined as described for the dielectric layer 3 in Embodiment 1.

In this embodiment, it is preferable that insulating materials are selected and combined and the thickness of dielectric layer 23 is determined depending on an interconnection distance, such that a capacitance (per a unit length) between second conductor layer 24a (signal interconnection) and first conductor layer 22 is larger than that (per a unit length) between the adjacent second conductor layers 24a in the same layer.

In the interconnection structure thus formed, second conductor layer 24a may act as a signal interconnection while first conductor layer 22 is connected to a reference potential, e.g., grounded to act as a ground layer or connected to a source to act as a source layer. FIG. 5(c) shows a configuration where first conductor layer 22 acts as a ground layer.

As described above, an interconnection structure where two conductor films are laminated via an insulating film may be formed and one patterned conductor layer may be used as a signal interconnection while the other planar conductor layer being connected to a reference potential to strengthen mutual electrostatic coupling of the facing conductor layers so that cross talk with an adjacent interconnection may be reduced.

Two conductor layers may be laminated to induce in one planar conductor layer a current with a phase opposite to a current in the other conductor layer (signal interconnection). Thus, forming electromagnetic coupling between these conductor layers whereby a crosstalk with another adjacent interconnection may be reduced.

Furthermore, as described in Embodiment 1, a configuration where conductor layers mutually facing via an insulating film to form a transmission line may reduce an effective inductance of the interconnection to permit a signal to be satisfactorily transmitted.

Again in this embodiment, as described in Embodiment 1, after patterning second conductor layer 24 and dielectric layer 23, a liner film may be formed for improving moisture resistance and adhesiveness and then second interlayer insulating film 25 may be formed.

Embodiment 5

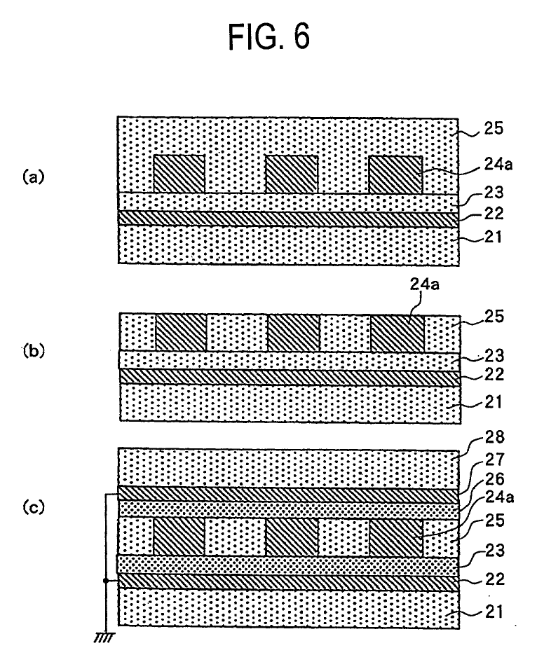

A fifth embodiment of the present invention is illustrated in FIG. 6(a)-(c).

FIG. 6(a)-(c) are cross-sections of the semiconductor device according to the fifth embodiment after various processing steps.

Referring now to FIG. 6(a), the structure illustrated may correspond and may be formed in a similar manner to the third embodiment of FIG. 4(c). In the process, it is preferable that second conductor layer 24a is slightly thicker in the light of subsequent polishing of its upper surface.

The product surface is polished by CMP (chemical mechanical polishing) until second conductor layer 24a is completely exposed as illustrated in FIG. 6(b).

Next, second dielectric layer 26, third conductor layer 27 and third interlayer insulating film 28 may be sequentially deposited to provide an interconnection structure shown in FIG. 6(c). Second dielectric layer 26, third conductor layer 27 and third interlayer insulating film 28 may be formed as are for first dielectric layer 23, first conductor layer 22 and first interlayer insulating film 21, respectively.

In this embodiment, it is preferable that first and second dielectric layers (23 and 26) have a dielectric constant higher than that of second interlayer insulating film 25 and may be made of any material described for the dielectric layer 3 in Embodiment 1. In addition, second interlayer insulating film 25 may be made of any material described for second interlayer insulating film 5 in Embodiment 1. A thickness of first or second dielectric layer (23 and 26) may be determined as described for dielectric layer 3 in Embodiment 1.

In this embodiment, it is preferable that insulating materials are selected and combined and the thicknesses of first and the second dielectric layers (23 and 26) are determined depending on an interconnection distance, such that capacitances (per a unit length) between second conductor layer 24a (signal interconnection) and first conductor layer 22 and between second conductor layer 24a and third conductor layer 27 are larger than that (per a unit length) between adjacent second conductor layers 24a in the same layer, respectively.

In the interconnection structure thus formed, second conductor layer 24a may act as a signal interconnection while first conductor layer 22 is connected to a reference potential, e.g., grounded to act as a ground layer or connected to a source to act as a source layer. Similarly, third conductor layer 27 is also connected to a reference potential to act as, for example, a ground or source layer. One of the layers sandwiching the signal interconnection layer may act as a ground layer while the other as a source layer, or both conductor layers may act as a source or ground layer. FIG. 6(c) shows a configuration where both conductor layers sandwiching the signal interconnection layer act as a ground layer.

In the above configuration of this embodiment, electrostatic coupling may be formed between both conductor layers vertically (i.e., perpendicular to the substrate plane) sandwiching the signal interconnection layer and the signal interconnection layer so that cross talk can be further reduced.

Two conductor layers may be laminated via an insulating film to induce in one planar conductor layer a current with a phase opposite to a current in the other conductor layer (signal interconnection) for forming electromagnetic coupling between these conductor layers. In this way, cross-talk with an adjacent interconnection may be reduced.

Furthermore, as described in Embodiment 3, a configuration where conductor layers mutually facing via an insulating film to form a transmission line may reduce an effective inductance of the interconnection to permit a signal to be satisfactorily transmitted.

Embodiment 6

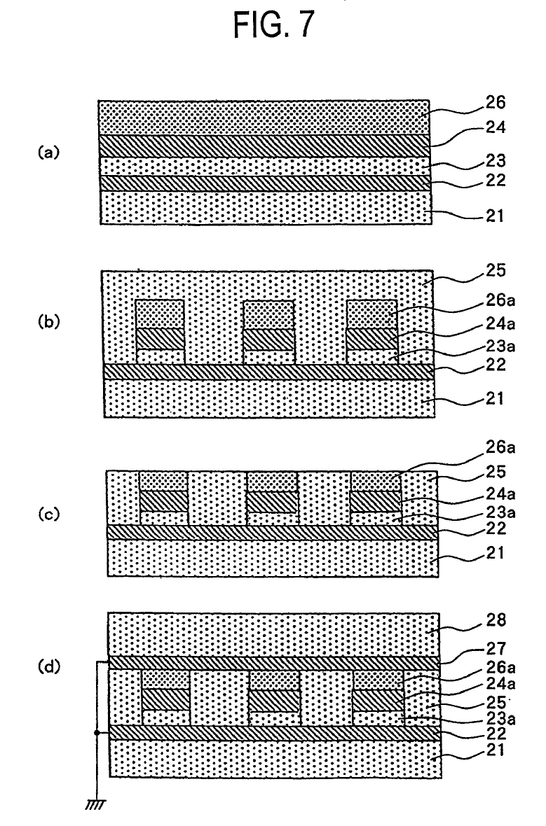

A sixth embodiment of the present invention is illustrated in FIG. 7(a)-(d).

FIG. 7(a)-(d) are cross-sections of the semiconductor device according to the sixth embodiment after various processing steps.

Referring now to FIG. 7(a), a first interlayer insulating film 21, a first conductor layer 22, a first dielectric layer 23, a second conductor layer 24, and a second dielectric layer 26 may be sequentially formed on a main surface of a semiconductor or ceramic substrate (not shown). In the process, it is preferable that second dielectric layer 26 which may be formed in the same manner as first dielectric layer 23 is slightly thicker in the light of subsequent polishing of its upper surface.

Next, second dielectric layer 26, second conductor layer 24, and first dielectric layer 23 may be patterned by a known lithography and dry etching technique. In the process, the dry etching step may be conducted under such conditions that etching is stopped when first conductor layer 22 is exposed.

Next, second interlayer insulating film 25 is formed covering second dielectric layer 26a, second conductor layer 24a, and first dielectric layer 23a (FIG. 7(b)). Second interlayer insulating film 25 is preferably made of a material having a dielectric constant smaller than that of first or second dielectric layers (23a and 26a). In this embodiment, as described in Embodiment 1, HSQ with a dielectric constant of approximately 3.1 may be used as a material for second interlayer insulating film 25 and silicon oxide is used as a material of first and second dielectric layers (23a and 26a).

The product surface may be polished by CMP until second dielectric layer 26a is completely exposed as illustrated in FIG. 6(b).

Next, third conductor layer 27 and third interlayer insulating film 28 may be sequentially deposited to provide an interconnection structure shown in FIG. 7(d). Third conductor layer 27 and third interlayer insulating film 28 may be formed in the same manner as first conductor layer 22 and first interlayer insulating film 21, respectively.

In this embodiment, it is preferable that first and second dielectric layers (23a and 26a) have a dielectric constant higher than that of second interlayer insulating film 25, and it is made of any material described for the dielectric layer in Embodiment 1. In addition, second interlayer insulating film 25 may be made of any material described for second interlayer insulating film 5 in Embodiment 1. A thickness of the final first or second dielectric layer (23a and 26a) may be determined as described for the dielectric layer 3 in Embodiment 1.

In this embodiment, it is preferable that insulating materials are selected and combined and the thickness of first and second dielectric layers (23a and 26a) are determined depending on an interconnection distance, such that capacitances (per a unit length) between second conductor layer 24a (signal interconnection) and first conductor layer 22 and between second conductor layer 24a and third conductor layer 27 are larger than that (per a unit length) between adjacent second conductor layers 24a in the same layer.

In the interconnection structure thus formed, second conductor layer 24a may act as a signal interconnection while first conductor layer 22 is connected to a reference potential, e.g., grounded to act as a ground layer or connected to a source to act as a source layer. Similarly, third conductor layer 27 is also connected to a reference potential to act as, for example, a ground or source layer. One of the layers sandwiching the signal interconnection layer may act as a ground layer while the other as a source layer, or both conductor layers may act as a source or ground layer. FIG. 7(d) shows a configuration where both conductor layers sandwiching the signal interconnection layer act as a ground layer.

In this embodiment, electrostatic coupling may be formed between both conductor layers vertically (i.e., perpendicular to the substrate plane) sandwiching the signal interconnection layer and the signal interconnection layer so that cross talk can be further reduced.

Two conductor layers may be laminated via an insulating film to induce in one planar conductor layer a current with a phase opposite to a current in the other conductor layer (signal interconnection) for forming electromagnetic coupling between these conductor layers whereby a cross-talk with an adjacent interconnection may be reduced.

Furthermore, as described in Embodiment 3, a configuration where conductor layers mutually facing via an insulating film to form a transmission line may reduce an effective inductance of the interconnection to permit a signal to be satisfactorily transmitted.

Embodiment 7

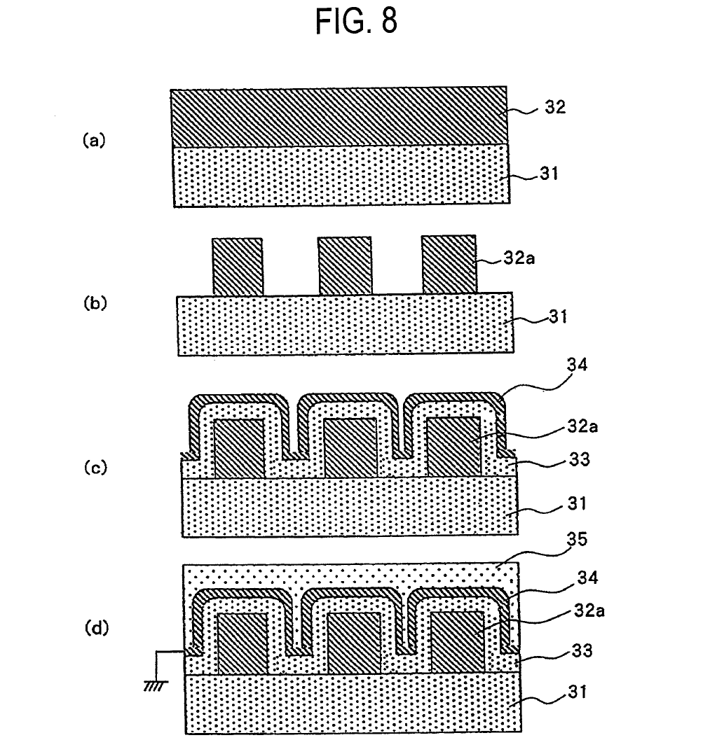

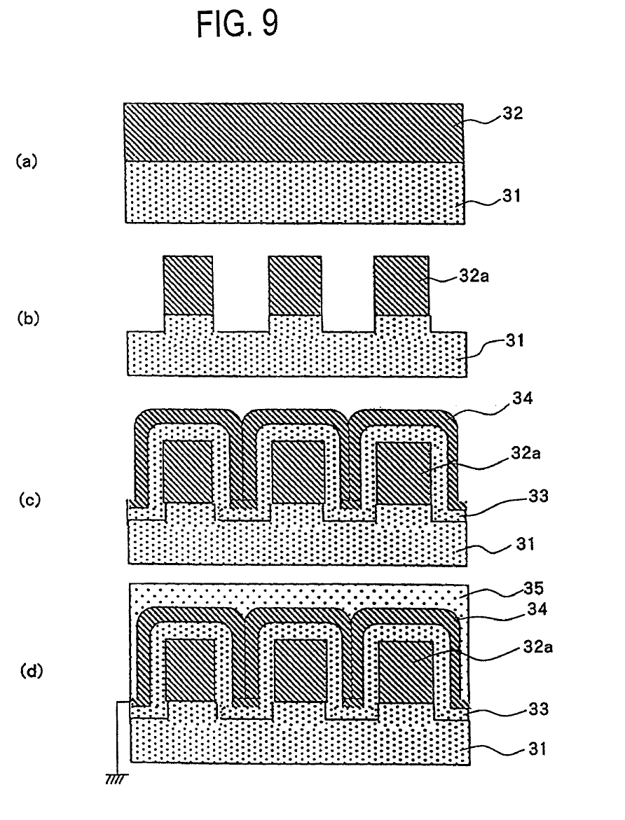

A seventh embodiment of the present invention is illustrated in FIG. 8(a)-(d) and FIG. 9(a)-(d).

FIGS. 8(a)-(d) and 9(a)-(d) are cross-sections of the semiconductor device according to the seventh embodiment after various processing steps.

Referring now to FIG. 8(a), a first interlayer insulating film 31 and a first conductor layer 32 may be sequentially formed on a main surface of a semiconductor or ceramic substrate (not shown). First interlayer insulating film 31 and first conductor layer 32 may be formed using a known material. In this embodiment, a silicon oxide film may be formed as the first interlayer insulating film 31 by PE-CVD while a barrier metal layer (TiN/Ti) and then an aluminum film are deposited as first conductor layer 32.

Next, first conductor layer 32 may be patterned by known a lithography and dry etching technique. In the process, the dry etching step may be conducted under such conditions that etching is stopped when first interlayer insulating film 31 is exposed (FIG. 8(b)). Alternatively, etching may reach to the side of the first interlayer insulating film from the interface of first conductor layer 32 and first interlayer insulating film 31 as shown in FIG. 9(b).

Next, there can be formed a dielectric layer 33 covering the patterned first conductor film 32a, on which is then formed the second conductor layer 34 (FIG. 8(c)). In the process, dielectric layer 33 must be sufficiently thin to prevent the layer from filling the space between first conductor layers 32a. In this embodiment, a silicon oxide film is formed by PE-CVD as dielectric layer 33, in the same manner as first interlayer insulating film 31. Second conductor layer 34 may be formed as usual using a known interconnection material. For example, titanium nitride (TiN) or tungsten (W) may be deposited by CVD.

In FIG. 8(c), there may be a gap between adjacent first conductor layers 32a, but when the gap is narrow, it may be filled with second conductor layer 34 as illustrated in FIG. 9(c). In FIG. 9(c), since interlayer insulating film 31 between first conductor layers 32a is etched, the whole lateral surface of first conductor layer 32a may be covered by second conductor layer 34 via dielectric layer 33.

Next, on second conductor layer 34, a second interlayer insulating film 35 may be formed using a known material (FIGS. 8(d), 9(d)). In this embodiment, a silicon oxide film may be formed by PE-CVD in the same manner as first interlayer insulating film 31.

In the interconnection structure thus formed, first conductor layer 32a may act as a signal interconnection while second conductor layer 34 is connected to a reference potential, e.g., grounded to act as a ground layer or connected to a source to act as a source layer. As described above, each signal interconnection layer 32a from its upper surface to its lateral surface may be covered by the second conductor layer 34 with the reference potential via dielectric layer 33 to allow each signal interconnection to be effectively shielded from an exogenous noise due to, for example, an adjacent interconnection. It may, therefore, effectively reduce cross-talk with an adjacent interconnection.

A configuration, where two conductor layers (second conductor layer 34 and each signal interconnection layer 32a) face each other via a relatively thinner insulating film, may induce in one conductor layer a current with a phase opposite to a current in the other conductor layer (signal interconnection) for forming electromagnetic coupling between these conductor layers. In this way, cross-talk with an adjacent interconnection may be reduced.

Furthermore, as described in Embodiment 1, a configuration where conductor layers mutually facing via an insulating film to form a transmission line may reduce an effective inductance of the interconnection to permit a signal to be satisfactorily transmitted. The conductor layer facing the signal interconnection via the insulating film may be acceptable as long as its shape (e.g., thickness) and composition are substantially even over at least its area facing the signal interconnection.

Embodiment 8

An eighth embodiment of the present invention is illustrated in FIG. 1 0(a)-(d).

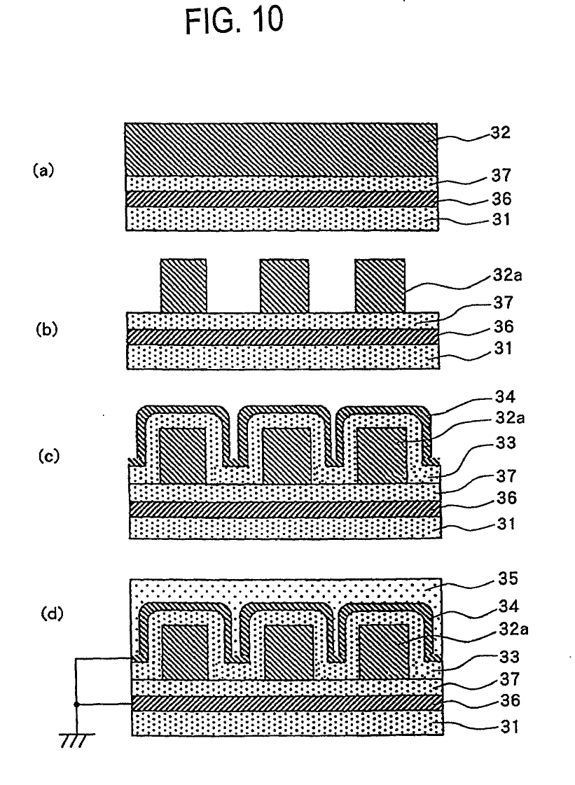

FIG. 10(a)-(d) are cross-sections of the semiconductor device according to the eighth embodiment after various processing steps.

Referring now to FIG. 10(a), a first interlayer insulating film 31, a third conductor layer 36, a second dielectric layer 37, and a first conductor layer 32 may be sequentially formed on a main surface of a semiconductor or ceramic substrate (not shown). Then, as shown in FIGS. 10(b) to (d), an interconnection structure may be formed as described in Embodiment 7. The second dielectric layer 37 and third conductor 36 layer may be formed as are for the first dielectric layer 33 and the second conductor layer 34 with the same materials, respectively.

Although first conductor layer 32 may be patterned such that etching is stopped when second dielectric layer 37 is exposed as shown in FIG. 10(b), etching may be proceeded to the substrate side from the interface of first conductor layer 32 and second dielectric layer 37 or to the degree that third dielectric layer 36 is exposed.

After forming second conductor layer 34, there is a gap between first conductor layers 32a in FIG. 10(c), but when the gap is narrow, it may be filled with second conductor layer 34.

In the interconnection structure thus formed, first conductor layer 32a may act as a signal interconnection while second conductor layer 34 is connected to a reference potential, e.g., grounded to act as a ground layer or connected to a source to act as a source layer. Similarly, third conductor layer 36 is also connected to a reference potential to act as, for example, a ground or source layer. One of the conductor layers may act as a ground layer while the other as a source layer, or both conductor layers may act as a source or ground layer. FIG. 10(d) shows a configuration where both conductor layers sandwiching the signal interconnection layer act as a ground layer.

In the interconnection structure of this embodiment, as shown in FIG. 10(d), each signal interconnection from its upper surface to its lateral surface may be covered by conductor layer 34 with the reference potential via first dielectric layer 33 and conductor layer 36 with the reference potential via dielectric layer 37 formed below the signal interconnection to allow each signal interconnection to be effectively shielded from an exogenous noise due to, for example, an adjacent interconnection. In this way, cross-talk with an adjacent interconnection may be reduced.

A configuration where two conductor layers (signal interconnection layer 32a and second conductor layer 34 or signal interconnection layer 32a and third conductor layer 36) face each other via a relatively thinner insulating film may induce in one conductor layer a current with a phase opposite to a current in the other conductor layer (signal interconnection) for forming electromagnetic coupling between these conductor layers whereby cross-talk with an adjacent interconnection may be reduced.

Furthermore, as described in Embodiment 1, a configuration where conductor layers mutually facing via an insulating film to form a transmission line may reduce an effective inductance of the interconnection to permit a signal to be satisfactorily transmitted. The conductor layer facing the signal interconnection via the insulating film may be acceptable as long as its shape (e.g., thickness) and composition are substantially even at least its area facing the signal interconnection.

Embodiment 9

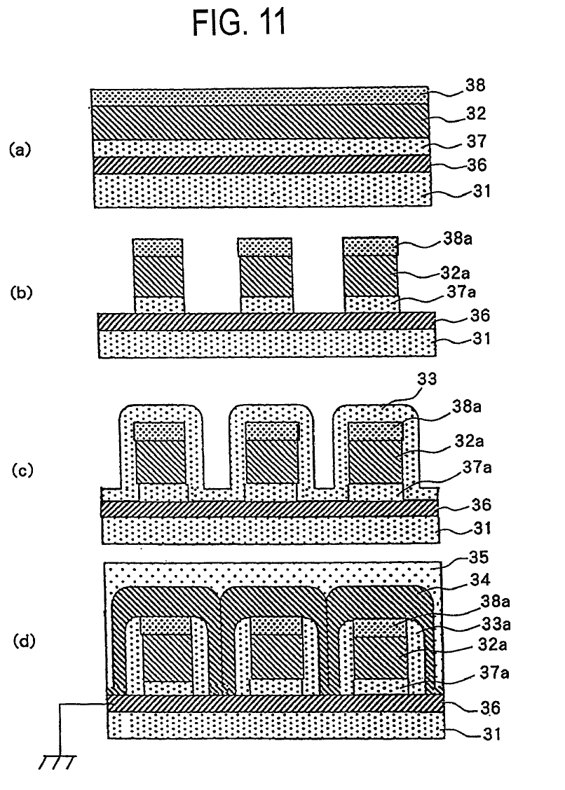

A ninth embodiment of the present invention is illustrated in FIG. 11(a)-(d).

FIG. 11(a)-(d) are cross-sections of the semiconductor device according to the ninth embodiment after various processing steps.

Referring now to FIG. 11(a), a first interlayer insulating film 31, a third conductor layer 36, a second dielectric layer 37, a first conductor layer 32, and a third dielectric layer 38 may be sequentially formed on a main surface of a semiconductor or ceramic substrate (not shown). Second and third dielectric layers (37 and 38) may be formed in the same manner as first dielectric layer 33 in Embodiment 7. First and third conductor layers (32 and 36) may be formed in the same manner as first and the second conductor layers (32 and 34) in Embodiment 7 with the same materials, respectively.

Next, third dielectric layer 38, first conductor layer 32, and second dielectric layer 37 may be patterned by a known lithography and dry etching technique. In the process, the dry etching step may be conducted under such conditions that etching may be stopped when third conductor layer 36 is exposed (FIG. 11(b)).

Next, there is formed a first dielectric layer 33 covering third dielectric layer 38a, first conductor layer 32a, and second dielectric layer 37a thus patterned (FIG. 11(c)). In the process, first dielectric layer 33 must be sufficiently thin to prevent the layer from filling the space between first conductor layers 32a.

Then, the product may be etched back to form a side-wall 33a on the lateral wall of first conductor layer 32a while exposing third conductor layer 36.

Next, a second conductor layer 34 may be formed, covering first conductor layer 32a via dielectric layers (33a and 38a), on which is deposited a second interlayer insulating film 35 to provide an interconnection structure illustrated in FIG. 1(d). Second conductor layer 34 and second interlayer insulating film 35 may be formed as described in Embodiment 7. The space between adjacent first conductor layers 32a may be filled with second conductor layer 34 in the structure shown in FIG. 11(d). However, when the distance between first conductor layers 32a is large, second conductor layer 34 may be formed for forming the space between adjacent first conductor layers 32a and then second interlayer insulating film 35 may be formed in the space.

In the interconnection structure thus formed, first conductor layer 32a may act as a signal interconnection while second and third conductor layers (34 and 36) are connected to a reference potential, e.g., grounded to act as a ground layer or connected to a source to act as a source layer. As described above, the periphery of each signal interconnection layer 32a may be covered by conductor layers (34 and 36) with the reference potential via dielectric layers (33a, 37a and 38a) to allow each signal interconnection to be effectively shielded from an exogenous noise due to, for example, an adjacent interconnection. It may, therefore, effectively reduce cross-talk with an adjacent interconnection.

A configuration where two conductor layers (signal interconnection layer 32a and the surrounding conductor layers (34 and 36)) face each other via a relatively thinner insulating film may induce in one conductor layer a current with a phase opposite to a current in the other conductor layer (signal interconnection) for forming electromagnetic coupling between these conductor layers whereby cross-talk with an adjacent interconnection may be reduced.

Furthermore, as described in Embodiment 1, a configuration where conductor layers mutually facing via an insulating film to form a transmission line may reduce an effective inductance of the interconnection to permit a signal to be satisfactorily transmitted. The conductor layer facing the signal interconnection via the insulating film may be acceptable as long as its shape (e.g., thickness) and composition are substantially even over at least its area facing the signal interconnection.

Embodiment 10

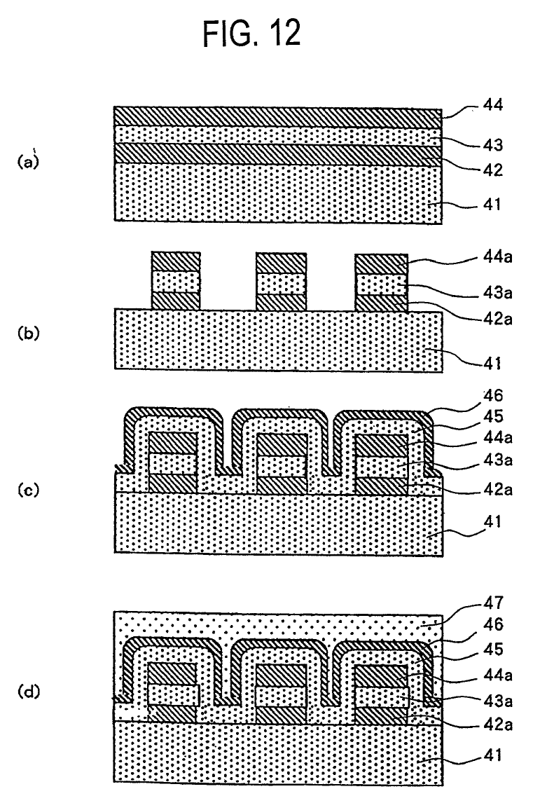

A tenth embodiment of the present invention is illustrated in FIG. 12(a)-(d).

FIG. 12(a)-(d) are cross-sections of the semiconductor device according to the tenth embodiment after various processing steps.

Referring now to FIG. 12(a), a first interlayer insulating film 41, a first conductor layer 42, a first dielectric layer 43, and a second conductor layer 44 may be sequentially formed on a main surface of a semiconductor or ceramic substrate (not shown).

Next, first conductor layer 42, first dielectric layer 43, and second conductor layer 44 may be patterned by a known lithography and dry etching technique. In the process, the dry etching step may be conducted under such conditions that etching is stopped when first interlayer insulating film 41 is exposed (FIG. 12(b)).

Next, a second dielectric layer 45 may be formed as usual covering first conductor layer 42a, first dielectric layer 43a, and second conductor layer 44a. Then a third conductor layer 46 is formed as usual (FIG. 12(c)). In the process, second dielectric layer 45 must be sufficiently thin to prevent the layer from filling the space between first conductor layers 44a. In FIG. 12(c), there is a gap between the adjacent first conductor layers 44a and when the gap is narrow, it may be filled with third conductor layer 46.

Then, a second interlayer insulating film 47 may be formed on third conductor layer 46 (FIG. 12(d)) in a usual manner using a known material.

In this embodiment, first and the second dielectric layers (43 and 45) and first and the second interlayer insulating films (41 and 47) may be formed using silicon oxide by PE-CVD while first, second and third conductor layers (42, 44, and 46) may be made of tungsten (W).

In the interconnection structure thus formed, second conductor layer 44a may act as a signal interconnection while first conductor layer 42a is connected to a reference potential, e.g., grounded to act as a ground layer or connected to a source to act as a source layer. Similarly, the third conductor layer 46 is also connected to a reference potential to act as, for example, a ground or source layer. One of the conductor layers may act as a ground layer while the other as a source layer, or both conductor layers may act as a source or ground layer.

In the interconnection structure of this embodiment, as shown in FIG. 12(d), each signal interconnection from its upper surface to its lateral surface may be covered by conductor layer 46 with the reference potential via dielectric layer 45 and conductor layers 42a as a pair with the reference potential via dielectric layer 43a is also formed below each signal interconnection to allow each signal interconnection to be effectively shielded from an exogenous noise due to, for example, an adjacent interconnection. It may, therefore, effectively reduce cross-talk with an adjacent interconnection.

A configuration where two conductor layers (signal interconnection layer 32a and first conductor layer 42a or signal interconnection layer 32a and third conductor layer 46) face each other via a relatively thinner insulating film may induce in one conductor layer a current with a phase opposite to a current in the other conductor layer (signal interconnection) for forming electromagnetic coupling between these conductor layers whereby a crosstalk with an adjacent interconnection may be reduced.

Furthermore, as described in Embodiment 1, a configuration where conductor layers mutually facing via an insulating film to form a transmission line may reduce an effective inductance of the interconnection to permit a signal to be satisfactorily transmitted. The conductor layer facing the signal interconnection via the insulating film may be acceptable as long as its shape (e.g., thickness) and composition are substantially even at least its area facing the signal interconnection.

Embodiment 11

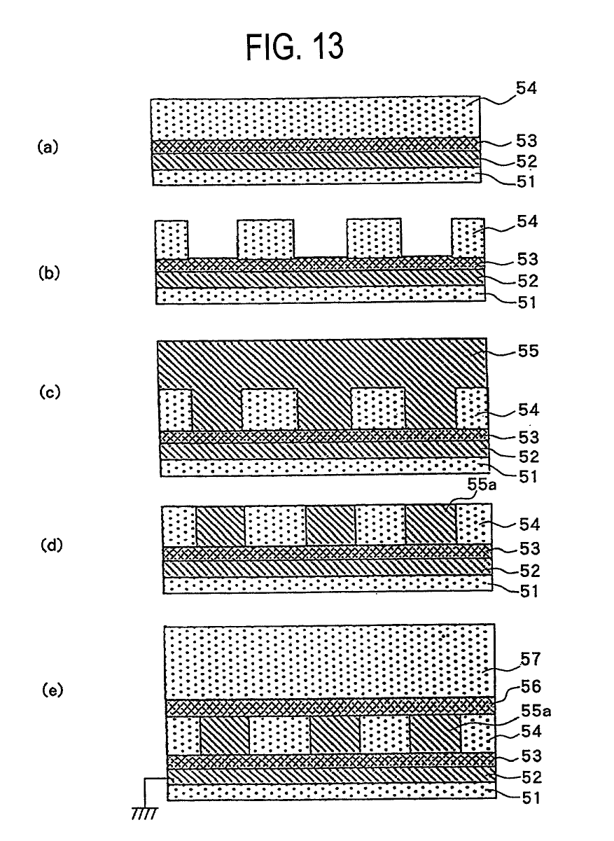

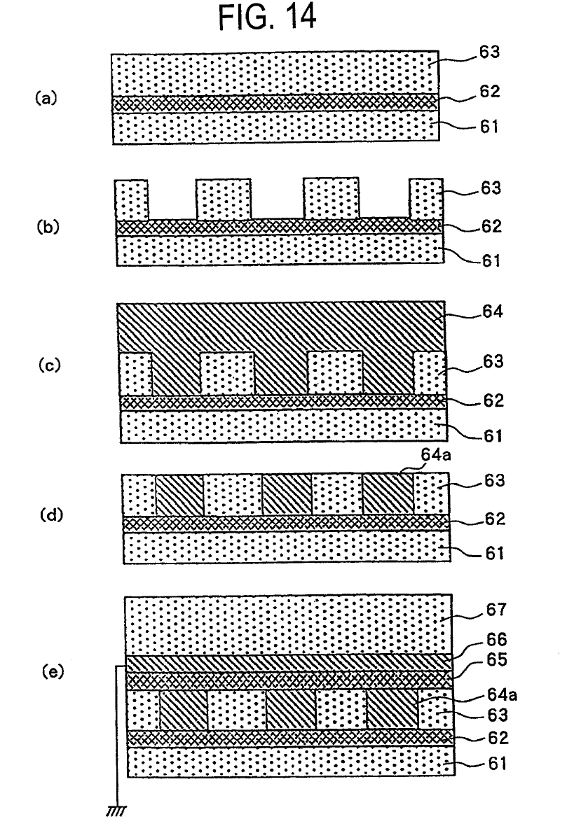

An eleventh embodiment of the present invention is illustrated in FIG. 13(a)-(e).

FIG. 13(a)-(e) are cross-sections of the semiconductor device according to the eleventh embodiment after various processing steps.

Referring now to FIG. 13(a), a first interlayer insulating film 51, a first conductor layer 52, a dielectric layer 53, and a second interlayer insulating film 54 may be sequentially formed on a main surface of a semiconductor or ceramic substrate (not shown).

First interlayer insulating film 51 may be a known insulating film formed as usual. In this embodiment, a silicon oxide film may be formed by PE-CVD. First conductor layer 52 may be formed as usual using a known interconnection material. In this embodiment, a tungsten (W) film is formed. In place of the tungsten film, a TiN film or a laminated film of W and TiN may be employed. It is preferable that dielectric layer 53 can act as an etching stopper film during etching second interlayer insulating film 54 later (i.e., it has a lower etching rate than the second interlayer insulating film) and has a higher dielectric constant than second interlayer insulating film 54. For example, in this embodiment, a silicon nitride film (a dielectric constant of SiN: approximately 7.1) or a silicon oxynitride film (a dielectric constant of SiON: approximately 5.5), which may be formed in a usual manner may be used. It is preferable that a thickness of dielectric layer 53 is smaller than a distance between adjacent second conductor layers 55a later formed. It is preferable that second interlayer insulating film 54 has a lower dielectric constant than dielectric layer 53. In this embodiment, an HSQ (dielectric constant: approximately 3.1) film is formed as usual.

Next, a trench with a given pattern may be formed in second interlayer insulating film 54 using a known lithography and dry etching technique (FIG. 13(b)). During the step of dry etching in the process, the dielectric layer 53 may act as an etching stopper film.

After depositing a barrier film made of Ta and TaN (not shown), a Cu film (not shown) may be formed as a seed layer. Then, a copper film may be formed by plating as the second conductor layer 55 over the whole surface such that it fills the trench (FIG. 13(c)).

Then, as shown in FIG. 13(d), the product is polished by CMP until the second interlayer insulating film 54 is completely exposed to form an interconnection pattern 55a where the trench is filled with copper.

Next, a third interlayer insulating film 56 is formed, which can act as a diffusion barrier for copper and an etching stopper during through-hole formation later. Third interlayer insulating film 56 may be a film made of, for example, SiN or SiC.

Then, a fourth interlayer insulating film 57 consisting of a known insulating film is formed. In this embodiment, a silicon oxide film is formed by PE-CVD.

In this embodiment, it is preferable that insulating materials are selected and combined and a thickness of the dielectric layer is determined depending on an interconnection distance, such that a capacitance (per a unit length) between the damascene copper interconnection (second conductor layer 55a) and first conductor layer 52 is larger than that (per a unit length) between the adjacent damascene copper interconnection layers 55a in the same layer.

In the interconnection structure thus formed, the damascene copper interconnection (second conductor layer 55a) may act as a signal interconnection while first conductor layer 52 is connected to a reference potential, e.g., grounded to act as a ground layer or connected to a source to act as a source layer. FIG. 13(e) shows a configuration where first conductor layer 52 acts as a ground layer.

As described above, an interconnection structure where two conductor layers are laminated via an insulating layer is formed and conductor layer 55a formed by a so-called damascene process is used as a signal interconnection while the other planar conductor layer 52 is connected to a reference potential to strengthen electrostatic coupling between two facing conductor layers so that cross-talk with an adjacent interconnection can be reduced.

A configuration where two conductor layers face each other via a relatively thinner insulating film may induce in one planar conductor layer a current with a phase opposite to a current in the other conductor layer (signal interconnection) for forming electromagnetic coupling between these conductor layers whereby cross-talk with an adjacent interconnection may be reduced.

Furthermore, as described in Embodiment 3, a configuration where conductor layers mutually facing via an insulating film to form a transmission line may reduce an effective inductance of the interconnection to permit a signal to be satisfactorily transmitted.

Embodiment 12

A twelfth embodiment of the present invention is illustrated in FIG. 14(a)-(e).

FIG. 1 4(a)-(e) are cross-sections of the semiconductor device according to the twelfth embodiment after various processing steps.

Referring now to FIG. 14(a), a first interlayer insulating film 61, a second interlayer insulating film 62, and a third interlayer insulating film 63 may be sequentially formed on a main surface of a semiconductor or ceramic substrate (not shown).

First interlayer insulating film 61 may be a known insulating film formed as usual. In this embodiment, a silicon oxide film is formed by PE-CVD. Second interlayer insulating film 62 may be a film which can act as an etching stopper film during etching third interlayer insulating film 63 later (i.e., it has a lower etching rate than the third interlayer insulating film); for example, in this embodiment, a silicon nitride (SiN), silicon oxynitride (SiON) or SiC film may be used. It is preferable that third interlayer insulating film 63 has a lower dielectric constant than a dielectric layer 65 formed later. In this embodiment, an HSQ (dielectric constant approximately 3.1) film is formed as usual.

Next, a trench with a given pattern is formed in third interlayer insulating film 63 using a known lithography and dry etching technique (FIG. 14(b)). During the step of dry etching in the process, second interlayer insulating film 62 may act as an etching stopper film.

After depositing a barrier film made of Ta and TaN (unshown), a Cu film (not shown) may be formed as a seed layer. Then, a copper film may be formed, by plating, as the first conductor layer 64 over the whole surface such that it fills the trench (FIG. 14(c)).

Then, as shown in FIG. 14(d), the product may be polished by CMP until third interlayer insulating film 63 is completely exposed to form an interconnection pattern 64a where the trench is filled with copper.

Next, a dielectric layer 65 which can act as a diffusion barrier for copper and an etching stopper during through-hole formation later, and then a second conductor layer 66 may be formed. Dielectric layer 65 is preferably made of a material with a higher dielectric constant than third interlayer insulating film 63; specifically, a film made of SiN or SiC may be used. The second conductor layer 66 may be a tungsten (W) film, a TiN film or a laminated film of W and TiN.

Then, a fourth interlayer insulating film 67 consisting of a known insulating film may be formed. In this embodiment, a silicon oxide film is formed by PE-CVD.

In this embodiment, it is preferable that insulating materials are selected and combined and a thickness of the dielectric layer is determined depending on an interconnection distance, such that a capacitance (per a unit length) between the damascene copper interconnection (first conductor layer 64a) and second conductor layer 66 is larger than that (per a unit length) between the adjacent damascene copper interconnection layers 64a in the same layer.

In the interconnection structure thus formed, the damascene copper interconnection (first conductor layer 64a) may act as a signal interconnection while second conductor layer 66 is connected to a reference potential, e.g., grounded to act as a ground layer or connected to a source to act as a source layer. FIG. 14(e) shows a configuration where second conductor layer 66 acts as a ground layer.

As described above, an interconnection structure where two conductor layers are laminated via an insulating layer is formed and conductor layer 64a formed by a so-called damascene process may be used as a signal interconnection while the other planar conductor layer 66 is connected to a reference potential to strengthen electrostatic coupling between two facing conductor layers so that cross-talk with an adjacent interconnection can be reduced.

A configuration where two conductor layers face each other via a relatively thinner insulating film may induce in one planar conductor layer a current with a phase opposite to a current in the other conductor layer (signal interconnection) for forming electromagnetic coupling between these conductor layers whereby cross-talk with an adjacent interconnection may be reduced.

Furthermore, as described in Embodiment 3, a configuration where conductor layers mutually facing via an insulating film to form a transmission line may reduce an effective inductance of the interconnection to permit a signal to be satisfactorily transmitted.

Embodiment 13

A thirteenth embodiment of the present invention is illustrated in FIG. 1 5(a)-(e).

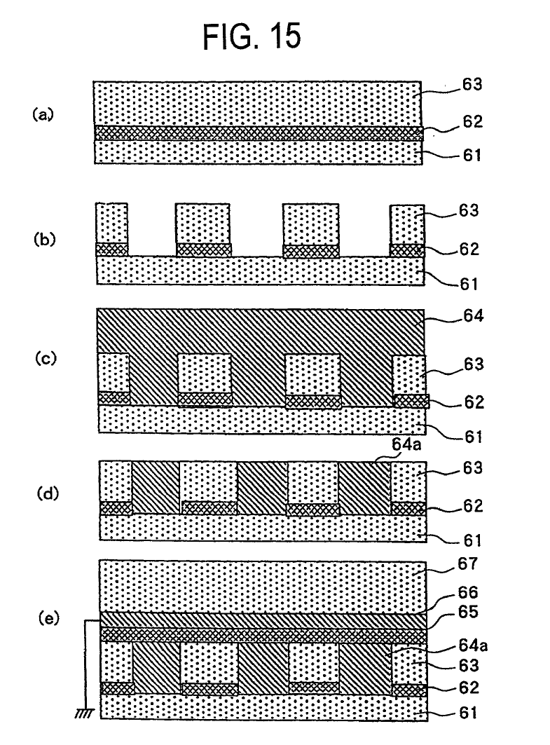

FIG. 15(a)-(e) are cross-sections of the semiconductor device according to the thirteenth embodiment after various processing steps.

In this embodiment, an interconnection is formed as described in Embodiment 12 except that in the etching step for forming a trench in third interlayer insulating film 63, second interlayer insulating film 62 at the bottom of the trench formed is further etched off to expose first interlayer insulating film 61, as shown in FIG. 15.

Embodiment 14

A fourteenth embodiment of the present invention is illustrated in FIG. 1 6(a)-(e).

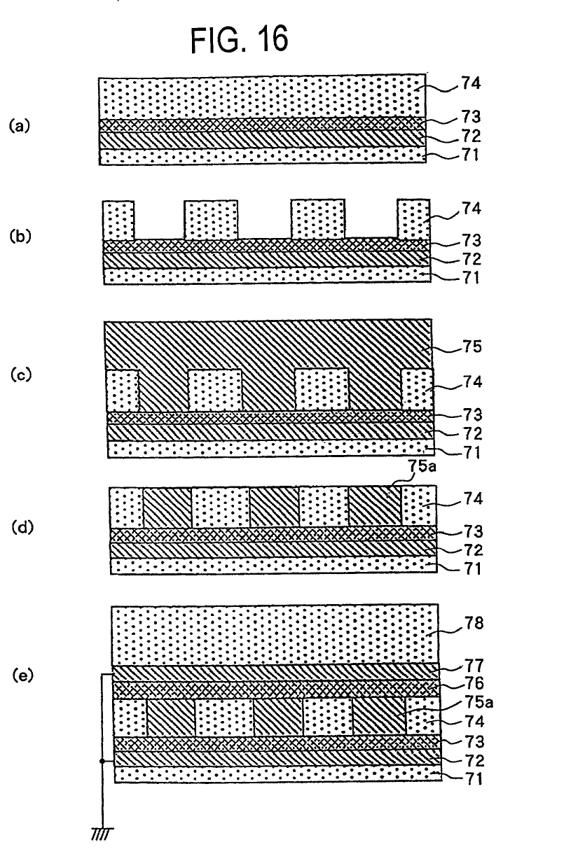

FIG. 16(a)-(e) are cross-sections of the semiconductor device according to the fourteenth embodiment after various processing steps.

Referring now to FIG. 16(a), a first interlayer insulating film 71, a first conductor layer film 72, a first dielectric layer 73, and a second interlayer insulating film 74 may be sequentially formed on a main surface of a semiconductor or ceramic substrate (not shown).

Then, a trench with a given pattern may be formed in second interlayer insulating film 74. A second conductor layer 75 is then formed such that the layer fills the trench, and subsequently the surface is polished by CMP to form a damascene copper interconnection 75a (FIGS. 16(a) to (d)).

Next, a second dielectric layer 76 which can act as a diffusion barrier for copper and an etching stopper during through-hole formation later, and then a third conductor layer 77 may be formed. Second dielectric layer 76 is preferably made of a material with a higher dielectric constant than second interlayer insulating film 74; specifically, a film made of SiN or SiC may be used. Third conductor layer 77 may be a tungsten (W) film, a TiN film or a laminated film of W and TiN.

Then, a third interlayer insulating film 78 consisting of a known insulating film may be formed. In this embodiment, a silicon oxide film is formed by PE-CVD.

In this embodiment, it is preferable that insulating materials are selected and combined and a thickness of the dielectric layer is determined depending on an interconnection distance, such that a capacitance (per a unit length) between the damascene copper interconnection (second conductor layer 75a) and first conductor layer 72 and a capacitance (per a unit length) between the damascene copper interconnection 75a and third conductor layer 77 are larger than that (per a unit length) between the adjacent damascene copper interconnection layers 75a in the same layer, respectively.

In the interconnection structure thus formed, second conductor layer 75a may act as a signal interconnection while first conductor layer 72 is connected to a reference potential, e.g., grounded to act as a ground layer or connected to a source to act as a source layer. Similarly, third conductor layer 77 is also connected to a reference potential to act as, for example, a ground or source layer. One of the layers sandwiching the signal interconnection layer may act as a ground layer while the other as a source layer, or both conductor layers may act as a source or ground layer. FIG. 16(e) shows a configuration where both conductor layers sandwiching the signal interconnection layer act as a ground layer.

In such a configuration according to this embodiment, electrostatic coupling is formed between both conductor layers vertically (i.e., perpendicular to the substrate plane) sandwiching the signal interconnection layer and the signal interconnection layer so that cross-talk can be more adequately reduced.

A configuration where two conductor layers face each other via a relatively thinner insulating film may induce in one planar conductor layer a current with a phase opposite to a current in the other conductor layer (signal interconnection) for forming electromagnetic coupling between these conductor layers whereby cross-talk with an adjacent interconnection may be reduced.

Furthermore, as described in Embodiment 3, a configuration where conductor layers mutually facing via an insulating film to form a transmission line may reduce an effective inductance of the interconnection to permit a signal to be satisfactorily transmitted.

Embodiment 15

A fifteenth embodiment of the present invention is illustrated in FIG. 1 7(a)-(e).

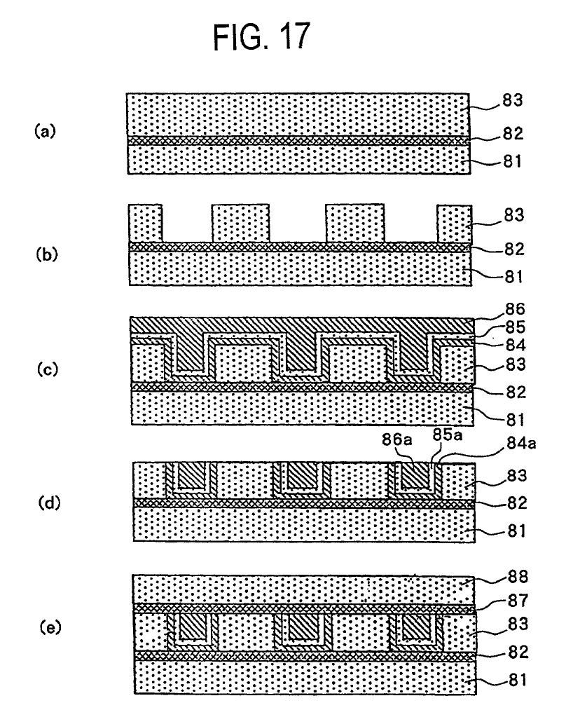

FIG. 17(a)-(e) are cross-sections of the semiconductor device according to the fifteenth embodiment after various processing steps.

Referring now to FIG. 17(a), a first interlayer insulating film 81, a second interlayer insulating film 82, and a third interlayer insulating film 83 may be sequentially formed on a main surface of a semiconductor or ceramic substrate (not shown).

First interlayer insulating film 81 may be a known insulating film formed in a usual manner. In this embodiment, a silicon oxide film is formed by PE-CVD. Second interlayer insulating film 82 may be a film which can act as an etching stopper film during etching third interlayer insulating film 83 later (i.e., it has a lower etching rate than the third interlayer insulating film). For example, when using a silicon oxide film as third interlayer insulating film 83, a silicon nitride (SiN) or silicon oxynitride (SiON) film may be used.

Next, a trench with a given pattern may be formed in third interlayer insulating film 83 using a known lithography and dry etching technique (FIG. 17(b)). During the step of dry etching in the process, second interlayer insulating film 82 may act as an etching stopper film.

Next, first conductor layer 84 covering the surface in the trench may be formed and on the layer a dielectric film 85 can be deposited. Then, after depositing a barrier film made of Ta and TaN (unshown), a Cu film (unshown) may be formed as a seed layer. Then, a copper film can be formed by plating, as second conductor layer 86, over the whole surface such that it fills the trench (FIG. 17(c)). As the first conductor layer 84, a known interconnection material may be deposited as usual; in this embodiment, a tungsten (W) film is formed. In place of the tungsten film, a TiN film or a laminated film of W and TiN may be employed. It is preferable that dielectric film 85 has a higher dielectric constant than third interlayer insulating film 83; in this embodiment, a silicon oxide film is formed by PE-CVD.

Then, as shown in FIG. 17(d), the product may be polished by CMP until third interlayer insulating film 83 is completely exposed to form an interconnection pattern 86a where the trench is filled with copper via first conductor layer 84a and dielectric layer 85a.

Next, a fourth interlayer insulating film 87 which can act as a diffusion barrier for copper and an etching stopper during through-hole formation later may be formed. The fourth interlayer insulating film 87 may be made of, for example, SiN or SiC.

Then, a fifth interlayer insulating film 88 consisting of a known insulating film may be formed. In this embodiment, a silicon oxide film is formed by PE-CVD.

In the interconnection structure thus formed, the damascene copper interconnection (second conductor layer 86a) may act as a signal interconnection while first conductor layer 84a is connected to a reference potential, e.g., grounded to act as a ground layer or connected to a source to act as a source layer.

As described above, an interconnection structure where two conductor layers are laminated via a thin insulating layer may be formed. The conductor layer 86a formed by a so-called damascene process may be used as a signal interconnection while the other conductor layer 84a can be connected to a reference potential to strengthen electrostatic coupling between two facing conductor layers so that each signal interconnection can be effectively shielded from an exogenous noise due to, for example, an adjacent interconnection because each signal interconnection layer 86a from its bottom surface to its lateral surface may be covered by conductor layer 84a with the reference potential via dielectric layer 85a. It can, therefore, effectively reduce cross-talk with an adjacent interconnection.

A configuration where two conductor layers face each other via a relatively thinner insulating film may induce in one conductor layer a current with a phase opposite to a current in the other conductor layer (signal interconnection) for forming electromagnetic coupling between these conductor layers whereby cross-talk with an adjacent interconnection may be reduced.

Furthermore, as described in Embodiment 1, a configuration where conductor layers mutually facing via an insulating film to form a transmission line may reduce an effective inductance of the interconnection to permit a signal to be satisfactorily transmitted.

Embodiment 16

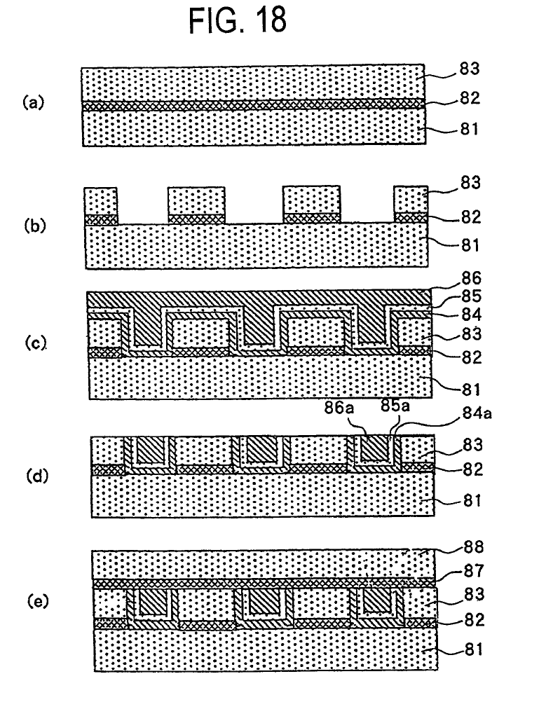

In this embodiment, an interconnection may be formed as described in Embodiment 15 except that in the etching step for forming a trench in the third interlayer insulating film 83, the second interlayer insulating film 82 at the bottom of the trench formed may be further etched off to expose the first interlayer insulating film 81, as shown in FIG. 18.

Embodiment 17: Interlayer Connection of Signal Interconnections

Next, there will be described an interlayer connection method for signal interconnections in an interconnection structure according to this invention. In this case, a conductor layer (a reference-potential layer such as a source layer or a ground layer) facing the signal interconnection may be planar. The connection method may ensure electric isolation between a plug in a through hole penetrating the planar conductor layer and the penetrated conductor layer.

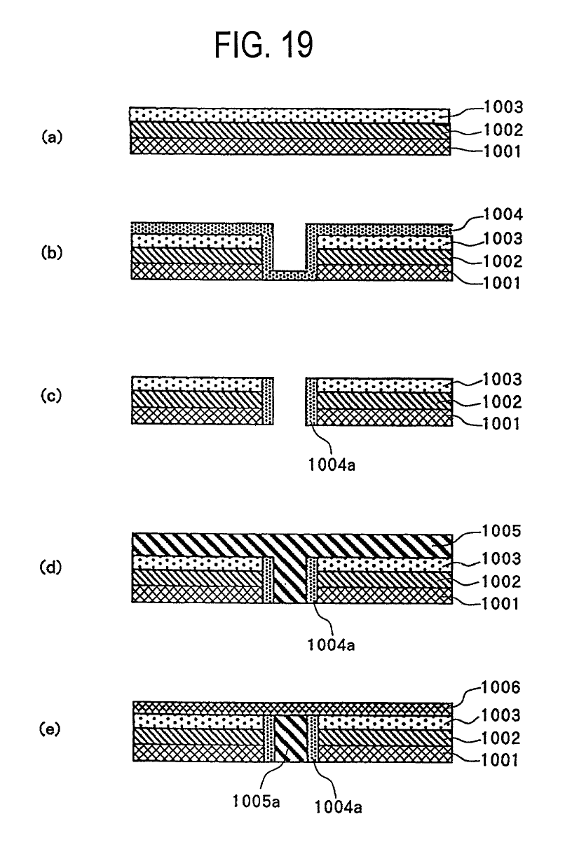

A seventeenth embodiment of the present invention is illustrated in FIGS. 19 to 21.

FIGS. 19-21 are cross-sections of the semiconductor device according to the seventeenth embodiment after various processing steps. In this embodiment, there is formed an interconnection structure as in Embodiment 13 (FIG. 15) where under the signal interconnection above which a facing planar conductor layer is disposed there is a planar conductor layer (corresponding to a planar conductor layer facing a signal interconnection in the lower layer) via an interlayer insulating film, and where the signal interconnection sandwiched by these planar conductor layers is connected in an interlayer manner to each of the signal interconnections in the upper and the lower layers.

Referring now to FIG. 19(a), a first interlayer insulating film 1001, a first conductor layer 1002, and a second interlayer insulating film 1003 may be sequentially formed on a main surface of a semiconductor or ceramic substrate (not shown).

Next, after forming a through hole penetrating these three layers in a given place, an insulating film for a side wall 1004 covering the inner wall of the through hole may be formed (FIG. 19(b)).

Then, the surface may then be etched back to form a side-wall insulating film 1004a as illustrated in FIG. 19(c).

As illustrated in FIG. 19(d), a conductor layer for plug formation 1005 may be formed, which fills the through hole.

Then, as illustrated in FIG. 19(e), a plug 1005a may be formed by CMP such that second interlayer insulating film 1003 can be completely exposed while leaving the conductor layer in the through hole. In place of CMP, etching back using dry etching may be employed. A third interlayer insulating film 1006 may then be formed, which can act as an etching stopper during forming a trench pattern in a fourth interlayer insulating film 1007 formed later. After forming third interlayer insulating film 1006, the procedure described in Embodiment 13 may be followed except the step of forming a plug.

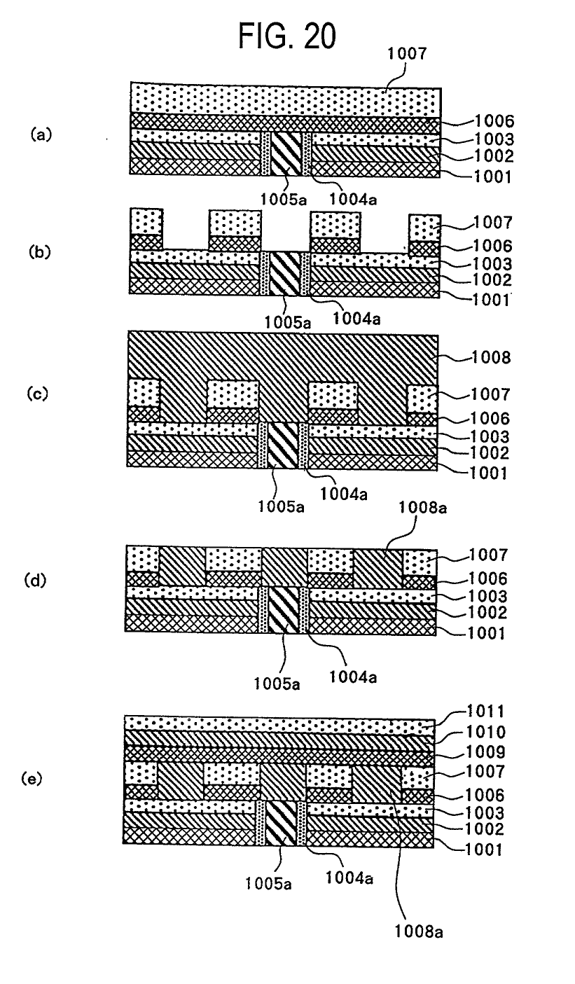

Then, as illustrated in FIG. 20(a), the fourth interlayer insulating film 1007 may be formed on third interlayer insulating film 1006.

Then, as illustrated in FIG. 20(b), a trench with a given pattern for forming a damascene interconnection may be formed by a known lithography and dry etching technique.

After depositing a barrier film and a seed layer, a copper film may be formed over the whole surface by plating as a second conductor layer 1008 and filling the trench as illustrated in FIG. 20(c).

Then, the copper film may be polished by CMP to form a damascene copper interconnection 1008a as illustrated in FIG. 20(d).

As illustrated in FIG. 20(e), a dielectric layer 1009, a third conductor layer 1010, and a fifth interlayer insulating film 1011 may be sequentially deposited.

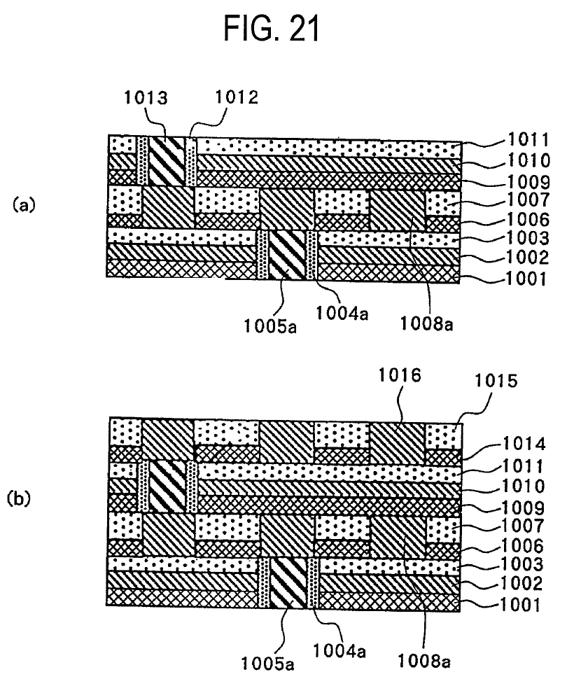

As described above with reference to FIG. 19, a through hole reaching the damascene copper interconnection 1008a may be formed. A side-wall insulating film 1012 may be formed on the inner wall of the through hole, and the through hole can be filled with a conductive material to form a plug 1013 (FIG. 21(a)).

Next, after forming a sixth interlayer insulating film 1014 which acts as an etching stopper, a seventh interlayer insulating film 1015 may be formed. Then, as described above with reference to FIGS. 20(a) to (d), a damascene copper interconnection 1016 may be formed.

The above process may be repeated to form a multi-layer interconnection.

According to the above process, signal interconnections may be readily connected between layers even when a conductor layer facing the signal interconnection is planar. It may, therefore, eliminate the necessity of leading out interconnections to an area without a planar conductor layer for interlayer connection.

Embodiment 18: Interlayer Connection Between a Source/Ground Line and a Conductor Layer

Now, there will be described a method for interlayer connection between a planar conductor layer (a reference-potential layer such as a source layer or a ground layer) facing a signal interconnection layer and a reference-potential line such as a source line or a ground line in an interconnection structure. This connection method may ensure electric isolation between a reference-potential plug (e.g., a source plug and a ground plug) in a through hole penetrating the planar conductor layer and the penetrated conductor layer.

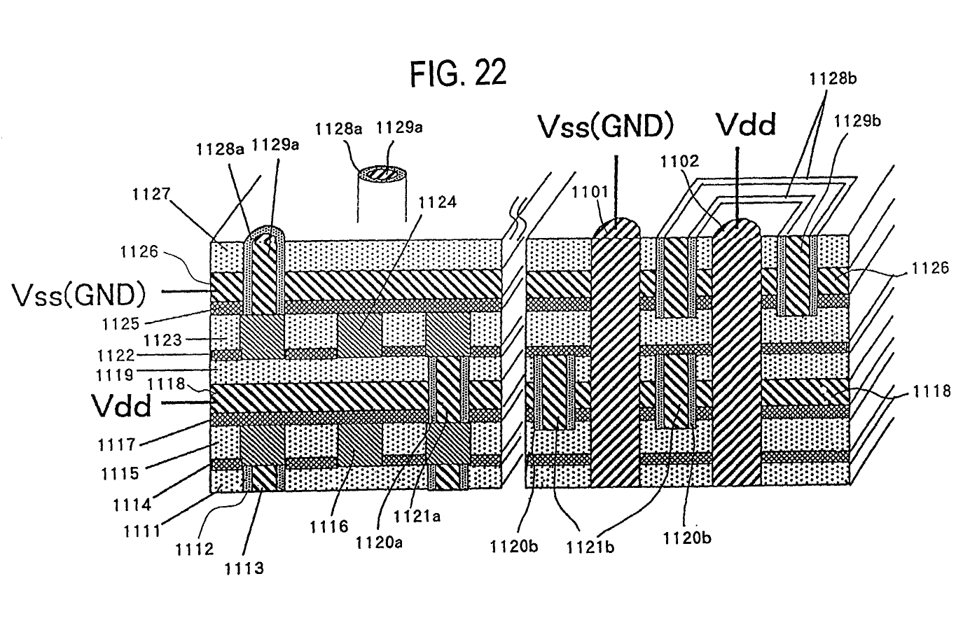

An eighteenth embodiment of the present invention is illustrated in FIG. 22.

FIG. 22 is a cross-section of the semiconductor device according to the seventeenth embodiment after various processing steps.

In the multi-layer interconnection structure according to this embodiment, the interconnection structure in Embodiment 13 (FIG. 15) is deposited via an interlayer insulating film. A planar conductor layer facing the signal interconnection in the upper layer acts as a ground layer (Vss) while a planar conductor layer facing the signal interconnection in the lower layer acts as a source layer (Vdd), and the signal interconnections of the upper and the lower layers are connected each other as described in Embodiment 17. In FIG. 22, 1111, 1114, 1115, 1119, 1122, 1123 and 1127 are interlayer insulating films; 1117 and 1125 are dielectric layers; 1116 and 1124 are signal interconnection layers; 1118 and 1126 are planar conductor layers; 1112, 1120a, 1120b, 1128a and 1128b are side-wall insulating films; and 1101, 1102, 1113, 1121a, 1121b, 1129a and 1129b are plugs.

The plug for a ground 1101 and the plug for a source 1102 may be formed by filling through holes in the interlayer insulating films with a conductive metal such that the plugs penetrate the planar conductive layers 1118 and 1126 after forming a multi-layer interconnection structure. In the process, the plug for a ground 1101 may be formed penetrating the insides of a circular through hole, side wall 1120b, and circular plug 1121b formed simultaneously with a through hole for interlayer connection of interconnections, side wall 1120a, and plug 1121a, respectively. On the other hand, the plug for a source 1102 may be formed penetrating the insides of a circular through hole, side wall 1128b and circular plug 1129b formed simultaneously with a through hole for interlayer connection of interconnections, side wall 1128a, and plug 1129a, respectively. It may allow electric isolation to be ensured between the plug for a ground 1101 and planar source layer 1118 as well as the plug for a source 1102 and planar ground layer 1126. Although circular plugs 1121b and 1129b may be formed by filling the circular through holes with a conductive material via the side walls, it is not always necessary to fill a circular hole with a conductive material. Alternatively, the circular hole may be vacant or completely filled with an insulating material. A shape of the circular through hole or the circular plug may be rectangular, square or circular in its plan view.

Embodiment 19: Charge Supply Via a Capacitor in a Chip

For achieving high-speed signal transmission, it may not only be important to form a transmission line with a return circuit near a signal interconnection, but also to place a charge source near a transistor as a switch because an inductance of a source or ground line may not be ignored for supplying charge with a high speed to a transmission line as a signal interconnection. Thus, for reducing such an inductance, a decoupling capacitor outside of a semiconductor chip equipped with an internal integrated circuit may be placed as closely to the chip as possible, whereby the capacitor may act as a charge source. Such a decoupling capacitor, which is originally used for preventing noise due to operation such as ON-OFF from another circuit, has been described in, for example, JP-A 7-307567 cited above. The publication has described that a film capacitor is mounted in a film multi-layer interconnection substrate as a bypass capacitor connected between positive and negative terminals in a power source for reducing ground bounce (signal reflected wave) in a multi-chip module.

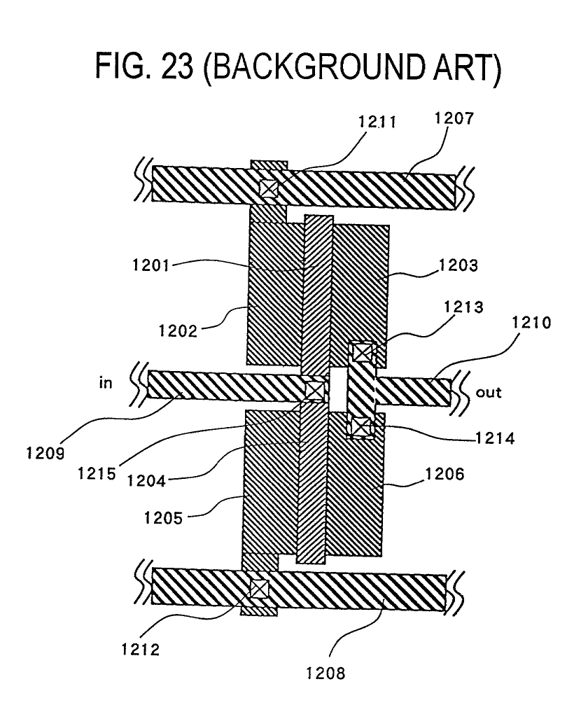

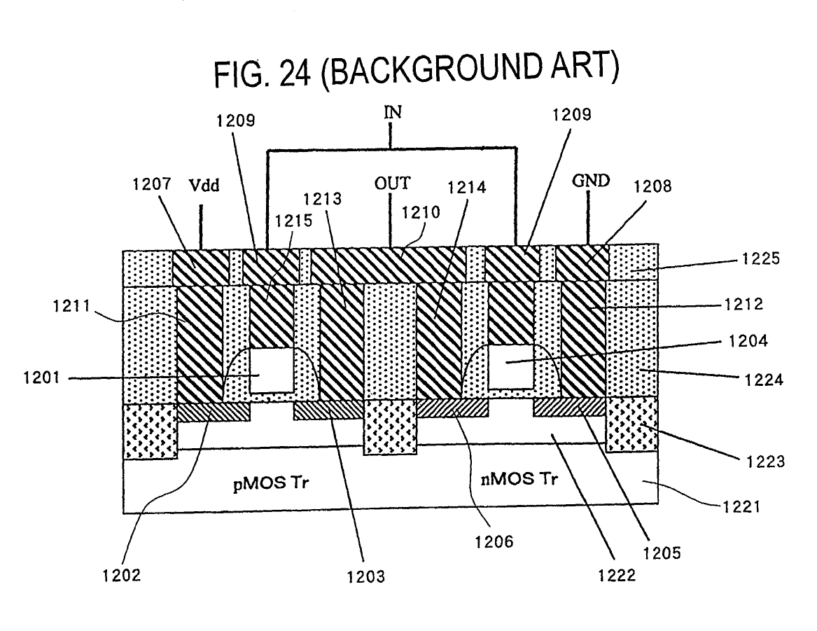

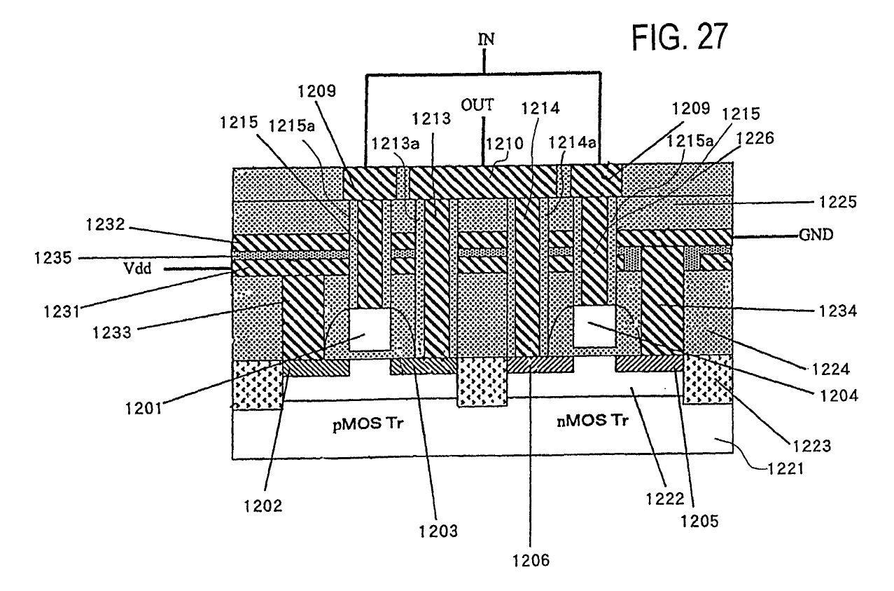

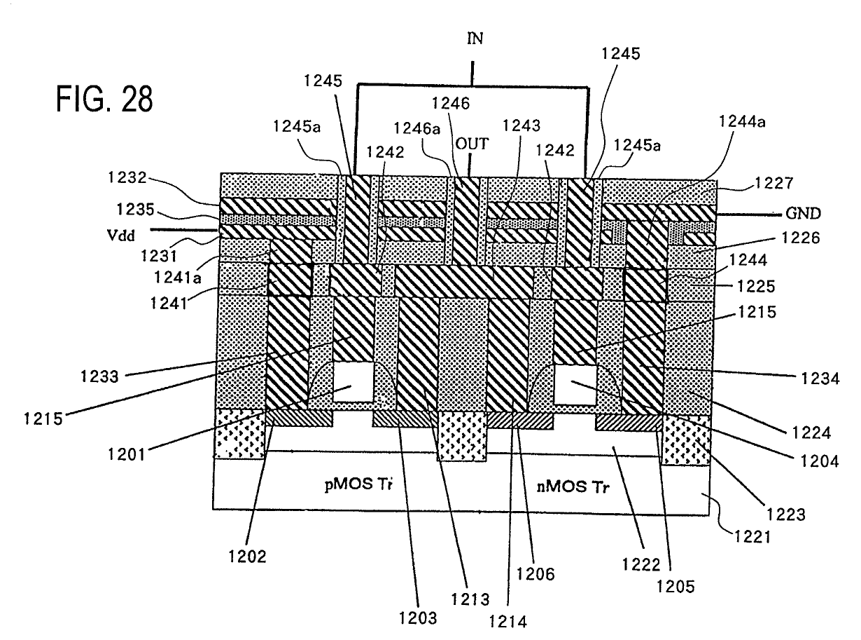

In an integrated circuit in a semiconductor chip, a power source has been, however, connected to a transistor via a source line and a ground line as illustrated in FIGS. 23 and 24. As an operation frequency has been increased to over G (giga) Hz, inductance of a source or ground line itself in a semiconductor chip has become significant. In FIGS. 23 and 24, 1201 and 1204 are gates; 1202, 1203, 1205 and 1206 are diffusion-layer areas; 1207 is a source line; 1208 is a ground line; 1209 is an input line; 1210 is an output line; 1211 to 1215 are contact plugs; 1221 is a semiconductor substrate; 1222 is a well area; 1223 is a device-separating area; 1224 and 1225 are interlayer insulating films; and Tr is a transistor. In FIG. 24, for illustration, serially-aligned gates are depicted in parallel and electric connections are depicted in such a manner that connection for each part may be clearly understood (it is also true in FIGS. 27 and 28).

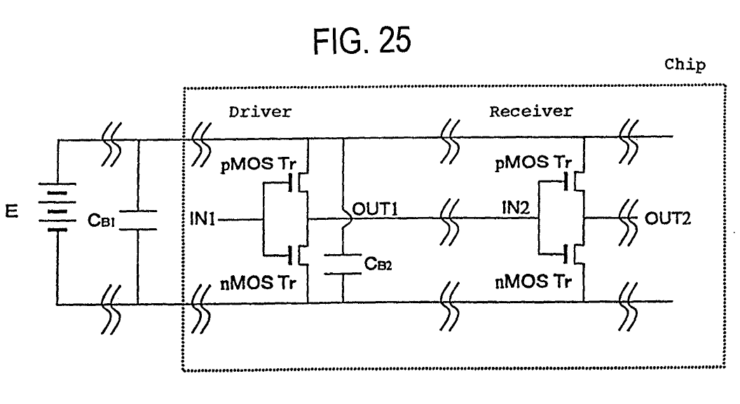

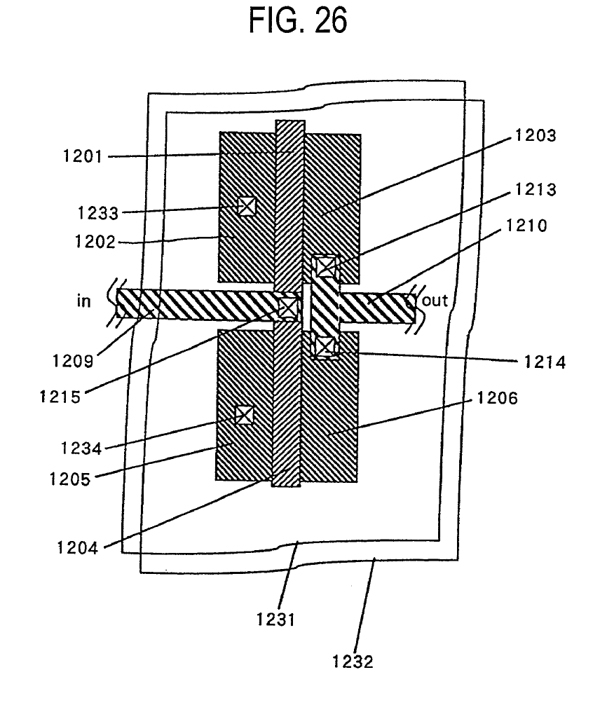

In this invention, for providing a structure which can reduce an impedance of a power source from a transistor, particularly an inductance of a power source, a film capacitor CB2 for charge supply is placed in a semiconductor chip (for example, a driver-receiver circuit illustrated in FIG. 25) in addition to a decoupling capacitor CB1 outside of the semiconductor chip, and the capacitor in the chip is used as a charge source.

FIGS. 26 and 27 show an embodiment of this invention where a film capacitor for charge supply is disposed just above a CMOS transistor as a driver circuit. In FIGS. 26 and 27, 1231 is a source plate; 1232 is a ground plate; 1235 is a dielectric film; 1213a, 1214a and 1215a are side-wall insulating films; and 1226 is an interlayer insulating film. Thus, placing a film capacitor composed of a source plate, a dielectric film and a ground plate in an area including a part just above a transistor in a semiconductor chip can reduce inductance of a source or ground line itself because the film capacitor acting as a charge source is near the transistor. Furthermore, since noise from the upper part may be blocked by the capacitor, the lower transistor may be protected from noise.

There will now be described a process for forming a configuration shown in FIG. 27.

First, on a semiconductor substrate 1221 is formed a CMOS transistor in a usual manner, on which may then formed an interlayer insulating film 1224, and then a contact hole reaching a diffusion-layer area 1202 may be formed.

The contact hole may be filled with a conducting material as usual to form a contact plug 1233. A conductor layer to be a source plate 1231 may then be formed and the source plate 1231 thus formed may then be electrically connected to the diffusion-layer area 1202. Alternatively, after depositing a conductor layer filling the contact hole when forming the contact plug 1233, the conductor layer may be left on the interlayer insulating film to a given thickness and the remaining conductor layer may be used as a source plate.

Next, after forming an opening in an area in the source plate 1231 above the diffusion-layer area 1205, an insulating film to be a dielectric layer 1235 may be deposited to, for example, approximately 15 nm.

In the opening in the source plate which is filled with a dielectric material can be formed a contact hole reaching the diffusion-layer area 1205, which may then be filled as usual to form a contact plug 1234.

Next, a conductor layer to be a ground plate 1232 can be formed and the ground plate 1232 thus formed may be electrically connected to the diffusion-layer area 1205. Alternatively, after depositing a conductor layer filling the contact hole when forming the contact plug 1234, the conductor layer may be left on the interlayer insulating film to a given thickness and the remaining conductor layer may be used as a ground plate.

Then, after forming an interlayer insulating film 1225, contact holes may be formed in given areas, side-wall insulating films (1213a to 1215a) may be formed in a usual manner on the inner walls of the contact holes, and then the contact holes can be filled with a conductor material to form contact plugs (1213 to 1215).

After forming an interlayer insulating film 1226, a trench with a given pattern may be formed. A copper film may be deposited in a usual manner such that the trench can be filled with copper, and interconnections (1209 and 1210) may be formed by CMP.

Embodiment 20

In the above embodiment (FIG. 27), the film capacitor for charge supply comprising the source plate, the dielectric film and the ground plate may be formed on the first interlayer insulating film on the transistor. Alternatively, after all given contact plugs to be electrically connected to a transistor on a substrate are formed in the first interlayer insulating film, a capacitor may be formed on the second or more interlayer insulating film.

FIG. 28 illustrates an embodiment having a configuration thus formed. The configuration may be formed as follows.

First, on a semiconductor 1221 is formed in usual manner, a CMOS transistor, on which can be formed the first interlayer insulating film 1224 and then given contact plugs (1213 to 1215, 1233 and 1234).

Then, after a second interlayer insulating film 1225, electric connections such as plugs and interconnections (1241 to 1244) may be formed.

Then, a third interlayer insulating film 1226 may be formed. A through hole reaching the electric connection 1241 may then be formed and the through hole can then be filled with a conductor material to form a plug 1241a. Then, a source plate 1231 may be formed and the source plate 1231 can be connected to the electric connection 1241 by the plug 1241a. In the process, after depositing a conductor layer filling the through hole, the conductor layer can be left on the interlayer insulating film to a given thickness and the remaining conductor layer may be used as a source plate.

Next, after forming an opening in an area in the source plate 1231 above the electric connection 1244, an insulating film to be a dielectric layer 1235 is deposited to, for example, approximately 15 nm.

In the opening in the source plate which may be filled with a dielectric material can be formed a through hole reaching the electric connection 1244, which can then be filled in a usual manner to form a plug 1244a.

Next, a conductor layer to be a ground plate 1232 can be formed and the ground plate 1232 thus formed may be electrically connected to the diffusion-layer area 1205. Alternatively, after depositing a conductor layer filling the through hole when forming the plug 1244a, the conductor layer can be left on the interlayer insulating film to a given thickness and the remaining conductor layer may be used as a ground plate.

Then, after forming the fourth interlayer insulating film 1227, through holes may be formed in given areas, side-wall insulating films (1245a and 1246a) may be formed in a usual manner on the inner walls of the through holes, and then the through holes can be filled with a conductor material to form plugs (1245 and 1246). The plugs (1245 and 1246) can be connected with an input and an output lines, respectively.

Other Embodiments

In this invention, a film capacitor for charge supply may have a multi-layer structure where a plurality of source and ground plates are alternately laminated via dielectric layers. Alternatively, two or more film capacitors where one source plate and one ground plate may be laminated via a dielectric layer may be stacked as a multi-layered structure via interlayer insulating films.

The above film capacitor for charge supply may be placed in a semiconductor chip while forming conductor layers, one of which is a signal interconnection, facing each other via an insulating film to form the above transmission line, so that a higher-frequency transmission signal can be stably transmitted, leading to accelerated device operation.

A source and a ground plates constituting a capacitor for charge supply in this invention may also act as a planar conductor layer facing a signal interconnection in the above interconnection structure of this invention by disposing a signal interconnection facing these planar conductor layers via an insulating film.

As seen in the above description, this invention provides a semiconductor device which may minimize increase of cross-talk or interconnection delay, provide stable signal properties and operate with a higher speed, and a manufacturing process whereby such a semiconductor device may be readily manufactured.

It is understood that the embodiments described above are exemplary and the present invention should not be limited to those embodiments. Specific structures should not be limited to the described embodiments.

Thus, while the various particular embodiments set forth herein have been described in detail, the present invention could be subject to various changes, substitutions, and alterations without departing from the spirit and scope of the invention. Accordingly, the present invention is intended to be limited only as defined by the appended claims.

What is claimed is:

1. A semiconductor device, comprising:
a first conductor electrically connected to a reference potential;
a second conductor acting as a first signal interconnection;
a first dielectric layer between the first and second conductors;
a third conductor acting as a second signal interconnection and adjacent to the second conductor; and
a first insulating film between the second and third conductors wherein a first capacitance between the second conductor and the first conductor is larger than the capacitance between the second conductor and the third conductor.

2. The semiconductor device according to claim 1, wherein:
the first dielectric layer has a thickness that is smaller than the distance between the second and third conductors.

3. The semiconductor device according to claim 1, wherein:
the first insulating film has a dielectric constant smaller than the first dielectric layer.

4. The semiconductor device according to claim 1, further including:
a fourth conductor electrically connected to the reference potential;
and
a second dielectric layer between the second and fourth conductors.

5. The semiconductor device according to claim 4, wherein the first and second dielectric layers each have a thickness smaller than a distance between the second and third conductors.

6. The semiconductor device according to claim 4, wherein:
the first insulating film has a dielectric constant smaller than the dielectric constants of the first and second dielectric layers.

7. The semiconductor device according to claim 4, wherein:
the first and second conductors are disposed in parallel and are separated by the first dielectric layer; and
the second and fourth conductors are disposed in parallel and are separated by the second dielectric layer.

8. The semiconductor device according to claim 1, wherein:
the first and second conductors are disposed in parallel and are separated by the first dielectric layer.

9. The semiconductor device according to claim 8, wherein:
the first and third conductors are disposed in parallel and are separated by the first dielectric layer.

10. The semiconductor device according to claim 1, wherein the second conductor is formed in a first trench having a predetermined pattern and the third conductor is formed in a second trench having a predetermined pattern.

11. The semiconductor device according to claim 1, wherein the first conductor, first dielectric layer and second conductor are formed in a trench having a predetermined pattern.

12. The semiconductor device according to claim 11, wherein the first conductor is separated from a bottom surface and at least a portion of a side surface of the second conductor by the first dielectric layer.

13. The semiconductor device according to claim 1, where in the first conductor layer and the second conductor layer form a transmission line.

14. A semiconductor device, comprising:
a first conductor layer on a first interlayer insulating film and electrically connected to a reference potential;
a first dielectric layer on the first conductor layer;
a signal interconnection on the first dielectric layer; and
a second conductor layer separated from the signal interconnection by a second dielectric layer and covering an upper surface and at least a portion of a side surface of the signal interconnection, the second conductor layer being electrically connected to the reference potential.

15. The semiconductor device according to claim 14, wherein the whole top surface and side surface of the signal interconnection is covered by the second conductor layer.

16. The semiconductor device according to claim 14, wherein:
the first conductor layer has a planar surface; and
a plurality of signal interconnections face and are separated from the planar surface by the first dielectric layer.

17. The semiconductor device according to claim 14, further including:
an adjacent signal interconnection on the first dielectric layer; and
the first and second conductor layers are electrically connected through a region between the signal interconnection and the adjacent signal interconnection.

18. The semiconductor memory device according to claim 14, further including:
an adjacent signal interconnection; and
a space between the signal interconnection and the adjacent signal interconnection is filled by the second conductor.

19. The semiconductor device according to claim 14, where the first conductor layer and the signal interconnection form a transmission line.

20. A process for manufacturing a semiconductor device, comprising the steps of:
forming a first conductor layer on a first interlayer insulating film;
forming a first dielectric layer on the first conductor layer;
forming a second interlayer insulating film;
forming a trench with a predetermined pattern in the second interlayer insulating film;
forming a second conductor layer filling the trench; and
polishing a resulting surface to form an interconnection where the second conductor layer is embedded in the trench.

21. The process according to claim 20, wherein:
the first dielectric layer acts as an etching stopper when forming the trench.

22. The process according to claim 20, further including the steps of:
forming a second dielectric layer on the surface including the second conductor layer; and
forming a third conductor layer on the second dielectric layer.

23. A process for manufacturing a semiconductor device, comprising the steps of:
forming an etching stopper film on a first interlayer insulating film;
forming a second interlayer insulating film on the etching stopper film;
forming a trench having a predetermined pattern in the second interlayer insulating film;
forming a first conductor layer filling the trench;
polishing a resulting surface to form a damascene interconnection where the first conductor is embedded in the trench;
forming a dielectric layer on the polished surface including the damascene interconnection; and
forming a second conductor layer on the dielectric layer.

24. A process for manufacturing a semiconductor device, comprising the steps of:
forming an etching stopper film on a first interlayer insulating film;
forming a second interlayer insulating film on the etching stopper film;
forming a trench having a predetermined pattern in the second interlayer insulating film;
forming a first conductor layer covering a surface in the trench;
forming a dielectric layer covering the surface in the trench;
forming a second conductor layer filling the trench; and
polishing a resulting surface with a chemical mechanical polish to form a damascene interconnection.

25. A process for manufacturing a semiconductor device, comprising the steps of:
forming a first conductor layer on a first interlayer insulating film;
forming a first dielectric layer on the first conductor layer;
forming a second conductor layer on the first dielectric layer;
forming a second dielectric layer on the second conductor layer;
patterning the first dielectric layer, the second conductor layer, and the second dielectric layer in a predetermined pattern;
forming a side-wall dielectric layer for the first dielectric layer, the second conductor layer, and the second dielectric layer; and
forming a third conductor layer separated from the second conductor layer by the second dielectric layer and the sidewall dielectric layer.

26. A semiconductor device, comprising:
a plurality of interconnection structures comprising a planar conductor layer electrically connected to a reference potential and a plurality of interconnections facing a surface of the planar conductor layer and separated by a dielectric layer;
a first through hole formed through the planar conductor layer; and
a first conductive plug formed in the first through hole and penetrating the planar conductor layer, the first plug being electrically isolated from the planar conductor.

27. The semiconductor device according to claim 26, further including:
the first conductive plug being electrically connected to a first reference potential;
a second through hole formed through the planar conductor layer; and
a second conductive plug formed in the second through hole and electrically connected to a second reference potential and penetrating the planar conductor layer, the second plug being electrically isolated from the planar conductor.

28. The semiconductor device according to claim 27, wherein an insulating film electrically isolates the first and second plugs from the planar conductor.

29. The semiconductor device according to claim 26, wherein the first through hole and first conductive plug are formed by the steps of:
forming the first through hole by penetrating the first conductive layer;
forming an insulating film on an inside surface of the first through hole;
etching the insulating film to form a side wall insulating film on a side surface of the inside surface of the first through hole; and
forming the first conductive plug in the first through hole.

30. The semiconductor device according to claim 29, wherein the step of forming the first conductive plug in the first through hole includes filling the first through hole with a conductive material and using chemical mechanical polishing to form the first conductive plug.

31. The semiconductor device according to claim 29, wherein the step of forming the first conductive plug in the first through hole includes filling the first through hole with a conductive material and an etching step to remove excess conductive material to form the first conductive plug.

32. A semiconductor device, comprising:
a first conductor electrically connected to a first reference potential;
a second conductor electrically connected to a second reference potential and separated from the first conductor by a dielectric layer and forming a film capacitor;
the film capacitor is formed in a region above a transistor in the semiconductor device; and
an interconnection structure including a plurality of third conductors separated from the first conductor by a first insulating layer.

33. The semiconductor device according to claim 32, wherein the interconnection structure includes a plurality of fourth conductors separated from the second conductor by a second insulating layer.
